(19) United States
(12) Patent Application Publication
(10) Pub. No.: US 2025/0006814 A1
(43) Pub. Date: Jan. 2, 2025

(54) SILICON CARBIDE DEVICE

(71) Applicant: Infineon Technologies AG, Neubiberg (DE)

(72) Inventors: Wolfgang LEHNERT, Freudenberg GT Lintach (DE); Fabian RASINGER, Villach (AT); Thomas AICHINGER, Faak am See (AT); Gerald RESCHER, Maria Saal (AT); Francisco Javier SANTOS RODRIGUEZ, St. Jakob im Rosental (AT); Carsten SCHAEFFER, Annenheim (AT); Armin TILKE, Dresden (DE)

(21) Appl. No.: 18/756,389

(22) Filed: Jun. 27, 2024

(30) Foreign Application Priority Data
Jun. 28, 2023 (DE) 102023206109.0

(51) Int. Cl. H01L 29/51; H01L 21/02; H01L 21/28; H01L 29/16; H01L 29/40; H01L 29/739; H01L 29/78

(52) U.S. Cl. CPC H01L 29/512; H01L 21/28255; H01L 29/1608; H01L 29/401; H01L 29/408; H01L 21/02123; H01L 21/02178; H01L 21/02181; H01L 21/02183; H01L 21/02186; H01L 21/02189; H01L 21/02192; H01L 21/0228; H01L 29/517; H01L 29/518; H01L 29/7397; H01L 29/7813

(57) ABSTRACT

A method for forming an interface layer on a silicon carbide body comprises removing an oxide layer from a surface of a silicon carbide body to obtain a silicon carbide surface. The silicon carbide body comprises a source region of a first conductivity type and a body region of a second conductivity type. The method further comprises after removing the oxide layer, depositing an interface layer directly on the silicon carbide surface. The interface layer has a thickness of less or equal to 15 nm. The method further comprises forming an electrical insulator over the interface layer, and forming a gate electrode over the electrical insulator.

### RELATED APPLICATION

This application claims priority to German Patent Application No. 102023206109.0, filed on Jun. 28, 2023, entitled “SILICON CARBIDE DEVICE”, which is incorporated by reference herein in its entirety.

### TECHNICAL FIELD

Examples of the present disclosure relate to a silicon carbide device, in particular to a silicon carbide device with a gate electrode and an electrical insulator disposed between the gate electrode and a silicon carbide body of the silicon carbide device and to a corresponding method for forming an electrical insulator.

### BACKGROUND

In a transistor, a gate electrode is typically electrically insulated from source, body and drift/drain regions of the transistor and is located adjacent the body region. The source region is usually connected to a source terminal and the drain region is usually connected to a drain terminal. For a silicon carbide device it may be desirable to adjust the electrical insulator between the gate electrode and the silicon carbide body.

### SUMMARY

A method for forming an interface layer on a silicon carbide body may comprise removing an oxide layer from a surface of a silicon carbide body to obtain a silicon carbide surface. The silicon carbide body may comprise a source region of a first conductivity type and a body region of a second conductivity type. The method may further comprise after removing the oxide layer, depositing an interface layer directly on the silicon carbide surface. The interface layer may have a thickness of less or equal to 15 nm. The method may further comprise forming an electrical insulator over the interface layer, and forming a gate electrode over the electrical insulator.

A silicon carbide device may comprise a source region of a first conductivity type formed in a silicon carbide body, a body region of a second conductivity type formed in the silicon carbide body, and a drain region. In addition, the silicon carbide device may comprise a gate electrode configured to switch a current between the source region and the drain region. The silicon carbide device may further comprise an interface layer disposed directly on the silicon carbide body and arranged between the silicon carbide body and the gate electrode. A thickness of the interface layer may be less or equal to 15 nm. The interface layer may comprise a first surface that is in contact with the silicon carbide body and a second surface that is opposing the first surface. A concentration of carbon within the interface layer may decrease along a direction that points from the first surface to the second surface from a first concentration of carbon at the first surface of the interface layer to a second concentration of carbon at a second surface of the interface layer opposing the first surface of the interface layer. The concentration of carbon may be less than half of the first concentration within at least 75% of the interface layer. The silicon carbide device may further comprise an electrical insulator disposed between the interface layer and the gate electrode. The electrical insulator may be configured to electrically insulate the gate electrode from the silicon carbide body.

### BRIEF DESCRIPTION OF THE DRAWINGS

The present disclosure is illustrated by way of example, and not by way of limitation, in the Figures of the accompanying drawings in which like reference numerals refer to similar or identical elements. The elements of the drawings are not necessarily to scale relative to each other. The features of the various illustrated examples can be combined unless they exclude each other.

FIG. 1A illustrates a vertical cross-sectional view of a silicon carbide device, specifically of a vertical silicon carbide device with a planar gate.

FIG. 1B illustrates a vertical cross-sectional view of a silicon carbide device, specifically of a vertical silicon carbide device with a gate disposed in a trench in accordance with the present disclosure.

FIG. 1C illustrates a typical profile of a carbon concentration within an interface layer.

FIG. 1D illustrates a profile of a carbon concentration with an interface layer in accordance with the present disclosure.

FIG. 1E illustrates a profile of a carbon concentration with an interface layer in accordance with the present disclosure.

FIG. 2 illustrates a vertical cross-sectional view of an electrical insulator of a silicon carbide device that is arranged between a silicon carbide body and a gate electrode in accordance with the present disclosure.

FIG. 3 illustrates a vertical cross-sectional view of an electrical insulator of a silicon carbide device that is arranged between a silicon carbide body and a gate electrode in accordance with the present disclosure.

FIG. 4 illustrates a method for forming an electrical insulator and a gate electrode on a silicon carbide body of a silicon carbide device in accordance with the present disclosure.

FIGS. 5A-5D illustrate vertical cross-sectional views of an electrical insulator of a silicon carbide device that is arranged between a silicon carbide body and a gate electrode in accordance with the present disclosure.

FIGS. 6A-6D illustrate vertical cross-sectional views of a silicon carbide device, specifically of a lateral silicon carbide device in accordance with the present disclosure.

FIG. 7A-7D illustrate vertical cross-sectional views of a silicon carbide device, specifically of a vertical silicon carbide device in accordance with the present disclosure.

FIG. 8 illustrates a method for forming an electrical insulator and a gate electrode on a silicon carbide body of a silicon carbide device in accordance with the present disclosure.

FIGS. 9A-9E illustrate vertical cross-sectional views of an electrical insulator of a silicon carbide device that is arranged between a silicon carbide body and a gate electrode in accordance with the present disclosure.

FIGS. 10A-10E illustrate vertical cross-sectional views of a silicon carbide device, specifically of a lateral silicon carbide device in accordance with the present disclosure.

FIG. 11A-11E illustrate vertical cross-sectional views of a silicon carbide device, specifically of a vertical silicon carbide device in accordance with the present disclosure.

### DETAILED DESCRIPTION

In the following detailed description, reference is made to the accompanying drawings, which form a part hereof and in which are shown by way of illustrations specific embodiments in which a silicon carbide device may be practiced. It is to be understood that other embodiments may be utilized and structural or logical changes may be made without departing from the scope of the present disclosure. For example, features illustrated or described for one embodiment can be used on or in conjunction with other embodiments to yield yet a further embodiment. It is intended that the present disclosure includes such modifications and variations. The examples are described using specific language, which should not be construed as limiting the scope of the appending claims. The drawings are not scaled and are for illustrative purposes only.

Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” may describe a permanent low-resistive ohmic contact between electrically connected elements, for example a direct contact between the concerned elements or a low-resistive connection via a metal and/or heavily doped semiconductor material.

The term “electrically coupled” may include that one or more intervening element(s) adapted for signal and/or power transmission may be connected between the electrically coupled elements, for example, elements that are controllable to temporarily provide a low-resistive connection in a first state and a high-resistive electric decoupling in a second state.

The term “ohmic contact” may describe a non-rectifying electrical junction between two electrically connected elements. The ohmic contact may have a linear or approximately linear current-voltage (I-V) characteristic such as a linear I-V curve in the first and third quadrant of the I-V diagram as with Ohm's law.

The Figures illustrate relative doping concentrations by indicating “−” or “+” next to the doping type “n” or “p”. For example, “n-” means a doping concentration which is lower than the doping concentration of an “n”-doping region while an “n+”-doping region has a higher doping concentration than an “n”-doping region. Doping regions of the same relative doping concentration do not necessarily have the same absolute doping concentration. For example, two different “n”-doping regions may have the same or different absolute doping concentrations.

Two adjoining doping regions of the same conductivity type and with different dopant concentrations may form a unipolar junction, such as, for example, an n/n+ or p/p+ junction along a boundary surface between the two doping regions. At the unipolar junction a dopant concentration profile orthogonal to the unipolar junction may show a step or a turning point, at which the dopant concentration profile changes from being concave to convex, or vice versa.

Ranges given for physical dimensions include the boundary values. For example, a range for a parameter y from a to b reads as a≤y≤b. The same holds for ranges with one boundary value like “at most” and “at least”.

The term “on” is not to be construed as meaning “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate).

The terms “power semiconductor device” and “SiC power device” may refer to semiconductor devices with a high voltage blocking capability of at least 30 V, for example 100 V, 600 V, 1.6 kV, 3.3 kV or more and with a nominal on-state current or forward current of at least 1 A, for example 10 A or more.

A silicon carbide device may include a transistor cell with a gate electrode and a source region. The source region may be formed in a silicon carbide body and has a conductivity type.

The silicon carbide body may have two essentially parallel main surfaces (such as a first main surface and a second main surface), which may have approximately the same shape and size, and a lateral surface connecting the edges of the two main surfaces. For example, the silicon carbide body may be a cylinder or a polygonal, such as, for example rectangular or hexagonal, prism with or without rounded edges. The silicon carbide body may have a surface extension along two horizontal directions and may have a thickness along a vertical direction perpendicular to the horizontal directions. The horizontal directions are also referred to as lateral directions in the following.

The material of the silicon carbide body may be single-crystalline silicon carbide, for example 15R—SiC (silicon carbide of 15R-polytype), or silicon carbide with hexagonal polytype like 2H—SiC, 4H—SiC or 6H—SiC, by way of example. In addition to the main constituents silicon and carbon, the silicon carbide body may include dopant atoms, for example nitrogen (N), phosphorous (P), beryllium (Be), boron (B), aluminum (Al) and/or gallium (Ga). The silicon carbide body may include further impurities, for example hydrogen, fluorine and/or oxygen.

The transistor cell may be or may include an insulated gate transistor cell with an insulated gate electrode. The gate electrode may be a planar gate electrode formed on a first main surface of the silicon carbide body or may be a trench gate electrode formed in a trench extending from a first main surface into the silicon carbide body. A combination of a planar and a trench gate electrode may also be possible.

The silicon carbide body may further include a drain/drift region. At least a portion of the drain/drift region may have the same conductivity type as the source region and may be effective as the drain of the transistor cell.

The transistor cell may further include a body region of a complementary conductivity type as the source region and the drift/drain region. The body region may spatially separate the source region and the portion of the drain/drift region. A gate dielectric may be formed between the gate electrode and the body region. An electric potential applied to the gate electrode controls the distribution of mobile charge carriers in the body region by a field effect.

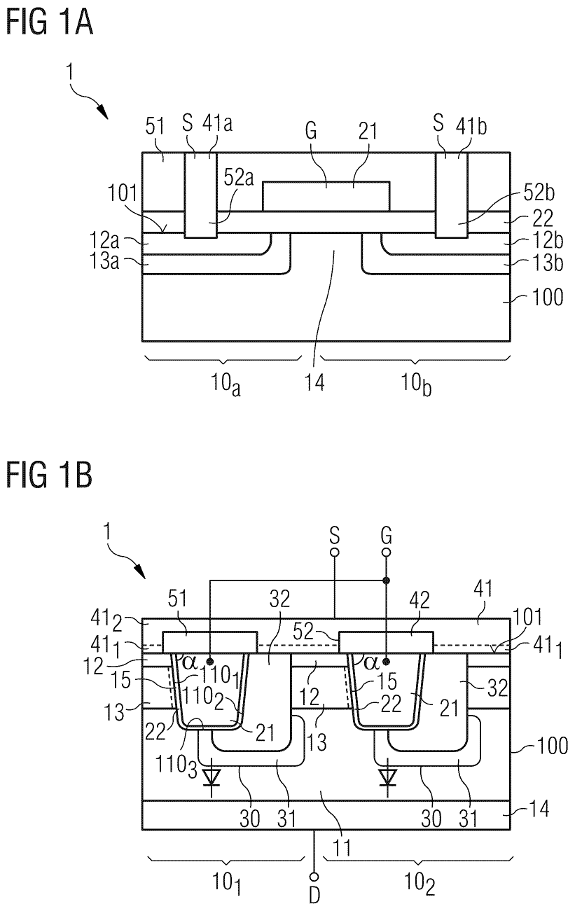

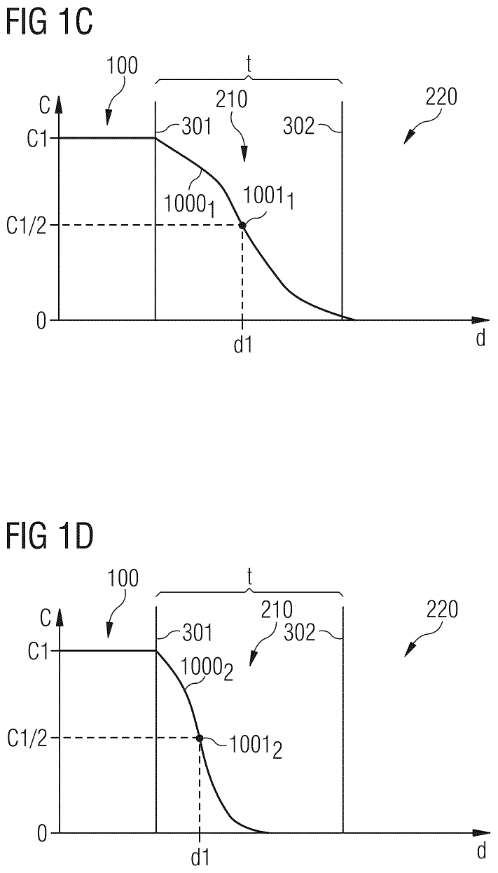

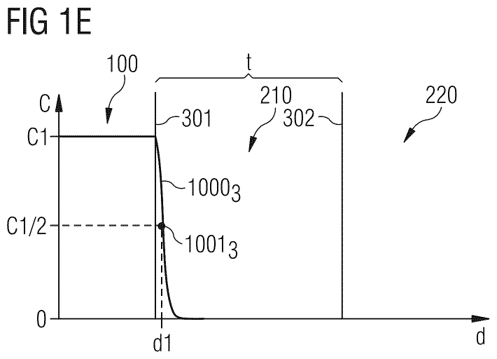

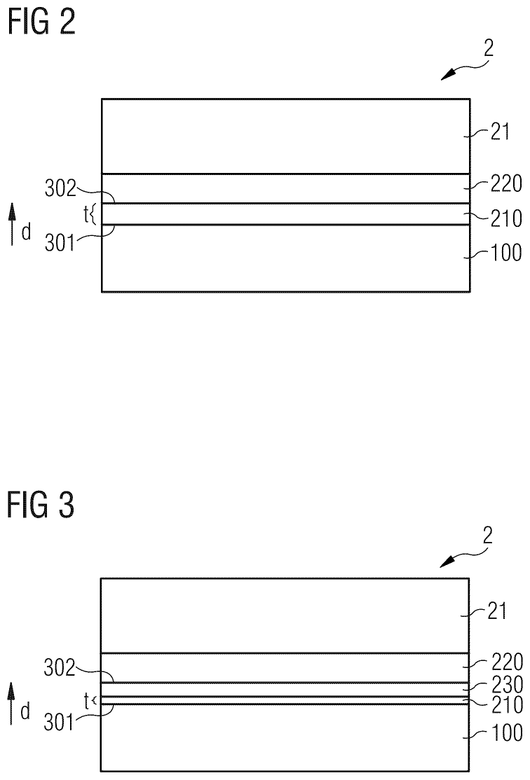

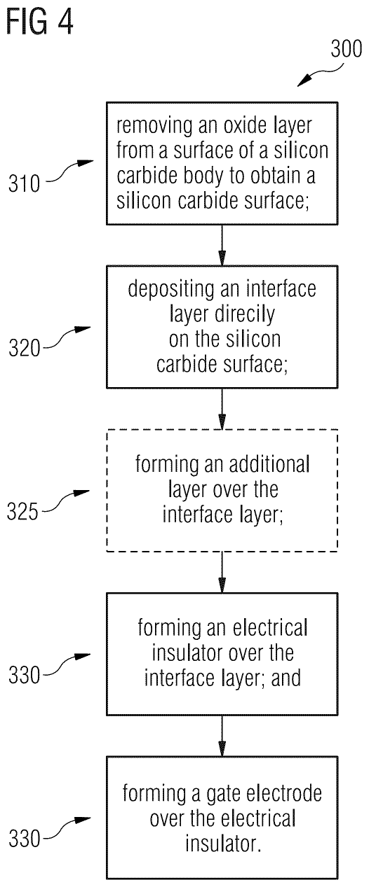

FIG. 1A illustrates a vertical cross-sectional view of a silicon carbide device 1, specifically of a vertical silicon carbide device with a planar gate structure. The silicon carbide device 1 includes a silicon carbide body 100 and one or more device cells 10a, 10b integrated in the silicon carbide body 100. The device cells will also be referred to as transistor cells in the following. In FIG. 1A, only one device cell 10 is illustrated. However, the silicon carbide device 1 may include more than two device cells, such as several ten, several hundred, several thousand, several ten thousand, several hundred thousand, or even several million device cells integrated in one silicon carbide body 100. Referring to FIG. 1A, the transistor cells 10a and 10b, each includes a source region 12, a body region 13, and a drift/drain region 14. The body region 13 may be arranged between the source region 12 and the drift/drain region 14.

Referring to FIG. 1A, the device cell 10a, 10b further includes a gate electrode 21 arranged on top of the silicon carbide device 1 (e.g., over parts of the body region 13) and electrically insulated from the silicon carbide body 100, including the source region 12, the body region 13, and the drift/drain region 14, by an electrical insulator 22. For example, the electrical insulator 22 may be implemented as a silicon oxide (SiO₂) or as a high-k material and may be arranged between the gate electrode 21 and the silicon carbide body 100. In some examples, the electrical insulator 22 may also extend over the source region 12 and the body region 13 (e.g., as a layer that covers the silicon carbide body 100). The gate electrode 21 of the device cell 10 may have a surface 21a (such as a planar surface) that is in contact with the electrical insulator 22. The body region 13 of the device cell 10 may adjoin the electrical insulator 22 so that the gate electrode 21 is arranged over the electrical insulator 22 and over the body region 13.

Still referring to FIG. 1A, an electrically insulating layer (insulation layer) 51 may cover the electrical insulator 22 and the gate electrode 21. The insulation layer 51 may have contact openings 52a, 52b where the insulation layer 51 and the electrical insulator 22 may uncover the source region 12a of the device cell 10a and the source region 12b of the device cell 10b. A first and second source electrode 41a, 41b may be formed within or on the insulation layer 51 and in the contact openings 52a, 52b. The source electrodes 41a, 41b may be electrically insulated from the gate electrode 21 by the insulation layer 51 and may electrically connect the source regions 12a and 12b to a source terminal S (only schematically illustrated in FIG. 1A) or may form the source terminal S. The source electrode 41 may be made of or include a material such as titanium (Ti), platinum (Pt), nickel (Ni), aluminum (AI), copper (Cu), metal alloys (such as nickel alloys) or the like.

Still referring to FIG. 1A, the silicon carbide device 1 may further include a drain/drift region 14 adjoining the body region 13. A drain electrode (not shown) may be formed on a second main surface of the silicon carbide body 100. The drain electrode may be made of or include a material such as titanium (Ti), platinum (Pt), nickel (Ni), aluminum (AI), copper (Cu), metal alloys (such as nickel alloys) or the like.

A plurality of device cells 10a, 10b may be connected in parallel by having the individual source regions 12a, 12b connected to the source terminal S via the source electrodes 41a and 41b, by having the individual drain regions 14 connected to the drain terminal, and by having the individual gate electrodes 21 electrically connected to a common gate terminal G. The connection of the gate electrodes 21 to the gate terminal G is only schematically illustrated in FIG. 1A.

The silicon carbide device 1 of FIG. 1A is a MOS transistor device that can be implemented as an n-type device or as a p-type device. In an n-type device, the source region 12 and the drain/drift region 14 are n-doped, while the body region 13 is p-doped. In a p-type device, the source region 12 and the drain/drift region 14 are p-doped, while the body region 13 is n-doped.

The silicon carbide device 1 of FIG. 1A can be operated like a conventional MOS transistor by applying a load voltage between the drain and source terminals and by applying a drive potential to the gate electrode G. This operating principle is briefly explained with reference to an n-type silicon carbide device 1. This operating principle, however, also applies to a p-type device, where in a p-type device the polarities of the voltages explained in the following have to be inverted. The silicon carbide device 1 is in a forward operation mode when a load voltage is applied between the drain and source terminals. This voltage is a positive voltage in an n-type device. In the forward operation mode, the MOS transistor can be switched on and off through the drive potential applied to the gate terminal G. The MOS transistor is switched on (in an on-state) when the drive potential applied to the gate terminal G generates conducting channels in the body region 13 between the source region 12 and the drain/drift region 14, and the MOS transistor is switched off (in an off-state) when the conducting channel in the body regions 13 are interrupted. The absolute value of the drive potential that switches on or switches off the transistor device is dependent on the specific type of the transistor device.

The device cell 10 includes a channel region, which is a region of the body region 13 along the electrical insulator 22. The channel region along the electrical insulator 22 enables charge carriers to flow from the source region 12 to the drain/drift region 14 when the transistor device is in the on-state.

The doping concentration of the drain/drift region 14 is, for example, between 1E14 cm⁻³ and 1E17 cm⁻³ (in the drift region) and, for example, higher than 1E19 cm⁻³ (in the drain region).

The doping concentration of the body regions 13 is, for example, between 5E16 cm⁻³ and 5E17 cm⁻³. The doping concentrations of the source region 12 is, for example, higher than 1E19 cm⁻³.

The gate electrode 21 can be an elongated gate electrode 21. For example, the gate electrode 21 can be connected to a gate terminal G at one or more positions that are out of view in the vertical cross-sectional view of FIG. 1A. The source electrode 41a, 41b may cover the insulation layer 51 in a region where the contact opening 52a, 52b is located and may be electrically connected to the source region 12a, 12b in the contact opening 52a, 52b. A gate connection electrode (not shown in FIG. 1A) may be spaced apart from the source electrode 41 and the drain electrode 43 in the first lateral direction x and may cover the insulation layer 51 in those regions where a contact opening (not shown in FIG. 1A) for the gate electrode 21 is arranged. The gate connection electrode 42 may be electrically connected to the gate electrodes 21 in the contact opening (not shown in FIG. 1A).

FIG. 1B illustrates a vertical cross-sectional view of a silicon carbide device 1, specifically of a vertical silicon carbide device, and more specifically of a vertical silicon carbide power device (optionally with an integrated diode). The silicon carbide device 1 includes a silicon carbide body 100 and one or more device cells 10₁, 10₂ integrated in the silicon carbide body 100. The device cells will also be referred to as transistor cells in the following. In FIG. 1B, only two device cells 10₁, 10₂ are illustrated. However, the silicon carbide device 1 may include more than two device cells, such as several ten, several hundred, several thousand, several ten thousand, several hundred thousand, or even several million device cells integrated in one silicon carbide body 100.

In FIG. 1B, the two device cells 10₁, 10₂ are labelled with different reference characters, while like features of the individual device cells 10₁, 10₂ are labelled with like reference characters. Referring to FIG. 1B, each transistor cell 10₁, 10₂ includes a drift region 11, a source region 12 and a body region 13. The body region 13 may be arranged between the source region 12 and the drift region 11. Each device cell 10₁, 10₂ may further (optionally) includes a diode region 30 and a pn junction formed between the diode region 30 and the drift region 11. In the embodiment of FIG. 1B, the individual device cells 10₁, 10₂ share the drift region 11. That is, the individual device cells 10₁, 10₂ have one drift region 11 in common.

Referring to FIG. 1B, each device cell 10₁, 10₂ further includes a gate electrode 21 arranged in a trench and electrically insulated from the silicon carbide body 100, including the body region 13, the diode region 30, and the drift region 11, by an electrical insulator 22. For example, the electrical insulator 22 may be implemented as a silicon oxide (SiO₂) or as a high-k material. The trench with the gate electrode 21 of each device cell 10₁, 10₂ has a first sidewall 110₁, a second sidewall 110₂, opposite the first sidewall 110₁ and a bottom 110₃. The body region 13 of each device cell 10₁, 10₂ adjoins the first sidewall 110₁ of the corresponding trench, the diode region 30 adjoins the second sidewall 110₂ of the corresponding trench, and the pn junction between the drift region 11 and the diode region 30 adjoins the bottom 110₃ of the corresponding trench.

Still referring to FIG. 1B, the individual diode region 30 of one device cell, such as device cell 10₁ may extend from a first surface 101 of the silicon carbide body 100 adjacent the source region 12 and the body region 13 of a neighbouring device cell, such as device cell 10₂, into the drift region 11 where the pn junction is formed. An electrically insulating layer (insulation layer) 51 may cover the first surface 101 and the gate electrodes 21. The insulation layer 51 may have contact openings 52 where the insulation layer 51 may uncover the diode regions 32 and the source regions 12 of the individual device cells 10₁, 10₂. A source electrode 41 may be formed on the insulation layer 51 and in the contact openings 52. The source electrode 41 may be electrically insulated from the gate electrodes 21 by the insulation layer 51 and may electrically connect the individual diode regions 30 and the individual source regions 12 to a source terminal S (only schematically illustrated in FIG. 1B) or may form the source terminal S. Optionally, the source electrode 41 may include a first source electrode layer 411 electrically contacting the diode regions 30 and the source regions 12, and a second source electrode layer 412 electrically connecting the first source electrode layer 411. The second source electrode layer 412 may be connected to the source terminal S or may form the source terminal S of the silicon carbide device 1. The first electrode layer 411 may include, for example, titanium (Ti), platinum (Pt), nickel alloys, or the like. The second electrode layer 412 may include, for example, aluminum (AI), copper (Cu), or the like.

Still referring to FIG. 1B, the silicon carbide device 1 may further include a drain region 14 adjoining the drift region 11. Optionally, a field-stop region (not illustrated) of the same doping type as the drift region 11 but more highly doped in the drift region 11 is arranged between the drift region 11 and the drain region 14. The drain region 14 may be electrically connected to a drain terminal D (only schematically illustrated in FIG. 1B). The individual device cells 10₁, 10₂ may share one drain region 14. That is, there may be one drain region 14 common to the individual device cells 10₁, 10₂.

The individual device cells 10₁, 10₂ may be connected in parallel by having the individual source regions 12 connected to the source terminal S via the source electrode 41, by sharing the drain region 14 and having the drain region 14 connected to the drain terminal D, and by having the individual gate electrodes 21 electrically connected to a common gate terminal G. The connection of the gate electrodes 21 to the gate terminal G is only schematically illustrated in FIG. 1B.

The silicon carbide device 1 of FIG. 1B is a MOS transistor device with an integrated diode. The transistor device can be implemented as an n-type device or as a p-type device. In an n-type device, the source regions 12 and the drift region 11 are n-doped, while the body region 13 is p-doped. In a p-type device, the source regions 12 and the drift region 11 are p-doped, while the body regions 13 are n-doped.

Further, the transistor device can be implemented as a MOSFET or as an IGBT. In a MOSFET, the drain region 14 has the same doping type as the source regions 12 and the drift region 11, while in an IGBT the drain region 14 has a doping type complementary to the doping type of the source regions 12 and the drift region 11. In an IGBT, the drain region 14 is also referred to as collector region.

The diode regions 30 may have the same doping type as the body regions 13, which is a doping type complementary to the doping type of the drift region 11. Since the diode region 30 of one device cell, such as device cell 10₁ in FIG. 1B, adjoins the body region 13 of a neighbouring device cell, such as device cell 10₂ in FIG. 1B, the body region 13 of each device cell is electrically connected to the source electrode 41 through the diode region 30 of a neighbouring device cell. Optionally, each diode region 30 includes two differently doped silicon carbide regions, namely a first region 31 adjoining the drift region 11 and forming the pn junction with the drift region 11, and a second region 32 electrically connecting the first region 31 to the source electrode 41. The second region 32, which will also be referred to as contact region in the following, may have a higher doping concentration than the first region 31. In the embodiment of FIG. 1B, the contact region 32 of one device cell, such as device cell 10₁ in FIG. 1B, may adjoin the second sidewall of the corresponding trench and electrically connects the body region 13 of the neighbouring device cell, such as device cell 10₂ in FIG. 1B, to the source electrode 41.

The diode region 30 of each device cell 10₁, 10₂ may form a diode with the drift region 11 and the drain region 14. A circuit symbol of this diode is also illustrated in FIG. 1B (the polarity of the circuit symbol illustrated in FIG. 1B relates to an n-type silicon carbide device; in a p-type device the polarity is inverted). The respective pn-junctions formed between the diode regions 30 of the individual device cells 10₁, 10₂ and the drift region 11 are connected in parallel and are connected in parallel with a load path (drain-source path) of the MOS transistor. The drain-source path of the MOS transistor is an internal path between the drain terminal D and the source terminal S. The individual diodes are reverse biased (block) when a voltage with a first polarity is applied between the drain and source terminals D, S of the MOS transistor, and the individual diodes are forward biased (conduct) when a voltage with a second polarity is applied between the drain and source terminals D, S. In an n-type silicon carbide device, the diodes are reverse biased when a positive voltage is applied between the drain and source terminals D, S, and the diodes are forward biased when a negative voltage is applied between the drain and source terminals D, S (which is a positive voltage between the source and drain terminals S, D). The individual diodes are parallel to the body diodes of the transistor cells. The body diodes are the diodes formed by the body regions 13 and the drift region 11 of the individual device cells 10₁, 10₂. However, unlike the body diodes, the properties of the diodes between the diode regions 30 and the drift region 11 can be adjusted widely independent of the properties of the MOS transistor. Specifically, the diodes between the diode regions 13 and the drift region 11 may be implemented to have a high current rating by implementing the diode region 30 such that the pn junction between the diode region 30 and the drift region 11 has a relatively large area.

The silicon carbide device 1 of FIG. 1B can be operated like a conventional MOS transistor by applying a load voltage between the drain and source terminals D, S and by applying a drive potential to the gate electrode G. This operating principle is briefly explained with reference to an n-type silicon carbide device. This operating principle, however, also applies to a p-type device, where in a p-type device the polarities of the voltages explained in the following have to be inverted. The silicon carbide device is in a forward operation mode when a load voltage is applied between the drain and source terminals D, S that reverse biases the body diodes and the additional diodes (the diodes between the diode regions 30 and the drift region 11) of the individual device cells 10₁, 10₂. This voltage is a positive voltage in an n-type device. In the forward operation mode, the MOS transistor can be switched on and off through the drive potential applied to the gate terminal G. The MOS transistor is switched on (in an on-state) when the drive potential applied to the gate terminal G generates conducting channels in the body regions 13 between the source regions 12 and the drift region 11, and the MOS transistor is switched off (in an off-state) when the conducting channel in the body regions 13 are interrupted. The absolute value of the drive potential that switches on or switches off the transistor device is dependent on the specific type of the transistor device (enhancement device or depletion device).

The silicon carbide device 1 is in a reverse operation mode when a voltage is applied between the drain and source terminals D, S that forward biases the body diodes and the additional diodes. In this operation mode, the silicon carbide device 1 can only be controlled through the polarity of the load voltage, but not through the drive potential applied to the gate terminal G.

When the silicon carbide device 1 is in the forward operation mode and when the silicon carbide device 1 is switched off, the pn-junctions between the diode regions 30 and the drift region 11 and the pn-junctions between the body regions 13 and the drift region 11 are reverse biased so that a depletion region expands in the drift region 11. When the load voltage increases, the depletion region expands deeper into the drift region 11 in the direction of the drain region 14. When the load voltage increases and the depletion region expands deeper into the drift region 11, the electric field strength at the pn-junctions also increase. Since the pn-junctions between the body regions 13 and the first drift region 11 is close to the electrical insulator 22, the electrical insulator 22 may be damaged when high load voltages are applied, that is when high field strengths occur. In the silicon carbide device 1 of FIG. 1B, however, the diode regions 30 of two neighboring device cells 10₁, 10₂ together with the drift region 11 may act as a JFET (Junction Field-Effect Transistor). This JFET has channel regions 111 between two neighboring diode regions 30. As the load voltage increases and as the electrical potential of the drift region 11 increases, the JFET pinches off the channel regions 111 and prevents a field strength of an electric field at the pn-junctions between the body regions 13 and the drift region 11 to further increase when the load voltage further increases. The load voltage at which the channels 111 of the JFET are pinched off, is, for example, dependent on a distance between two neighboring diode regions 30 in a lateral direction of the silicon carbide body 100. The “lateral direction” of the silicon carbide body 100 is perpendicular to the vertical direction, in which the drain region 14 is spaced from the body regions 13 and the diode regions 30, and is essentially parallel to the first surface 101. This lateral distance between two neighboring diode regions 30 is, for example, between 0.5 μm (micrometers) and 2 μm (micrometers) or between 0.25 times and 1.5 times the width of the trenches accommodating the gate electrodes 21. The “width” of the trenches is the distance between the first and second sidewalls 110₁, 110₂. In case the trenches are tapered, as illustrated in the embodiment of FIG. 1B, the width is the largest distance between the first and second sidewalls.

Each device cell 10₁, 10₂ includes a channel region, which is a region of the body region 13 along the electrical insulator 22 or which is the optional channel region 15 (illustrated in dashed lines in FIG. 1B). The channel region along the electrical insulator 22 enables charge carriers to flow from the source regions 12 to the drift region 11 when the transistor device is in the on-state. The diode region 30 of each device cell 10₁, 10₂ does not overlap the channel region. That is the pn junctions between the diode regions 30 and the drift region 11 adjoin the bottom of the individual gate trenches and do not extend beyond the gate trenches in the direction of the channel regions. Thus, the diode regions 30 do not constrain a charge carrier flow from the channel regions to the drain region 14.

The voltage blocking capability of the silicon carbide device 1 is, inter alia, dependent on a distance between the diode regions 30 and the drain region 14. This distance can be adjusted in the manufacturing process in accordance with the desired voltage blocking capability. As a rule of thumb, in a silicon carbide body 100, the distance between the drain region 14 and diode region 30 is between 0.8 micrometers and 1.0 micrometers per 100V voltage blocking capability.

The doping concentration of the drift region 11 is, for example, between 1E14 cm⁻³ and 1E17 cm⁻³. The doping concentration of the body regions 13 is, for example, between 5E16 cm⁻³ and 5E17 cm⁻³. The doping concentrations of the source and drain regions 12, 14 are, for example, higher than 1E19 cm⁻³. The doping concentration of the diode regions 30 is, for example, between 1E18 cm⁻³ and 1E19 cm⁻³.

Still referring to FIG. 1B, the body region 13 of each device cell 10₁, 10₂ adjoins the corresponding gate trench at the first sidewall 110₁. Especially when the gate trenches have tapered sidewalls, the first and second sidewalls 110₁, 110₂ may correspond to different crystal planes of a crystal lattice of the silicon carbide body 100. According to one embodiment, the silicon carbide body 100 includes a hexagonal SiC crystal and the gate trenches have tapered sidewalls, such that the first sidewall 110₁ corresponds to the 11-20-plane in the SiC crystal. In this case the individual channel regions feature a relatively low resistance. In this embodiment, the first sidewall 110₁ is aligned with the c-axis of the crystal of the silicon carbide body. The c-axis (hexagonal main axis) is perpendicular to the growth plane (0001-plane) of the SiC crystal. This growth plane is not illustrated in FIG. 1B. The bottom 110₃ of the trench is essentially parallel to the first surface 101.

An angle α (alpha) between the first sidewall 110₁ and the first surface 101 of the trench 110 is dependent on an orientation of the first surface relative to the growth plane (0001-plane). According to one embodiment, the first surface 101 is inclined relative to the growth plane, where an angle between the first surface 101 and the growth plane may be between 1° and 10°, in particular between 2° and 8°. In this case a is between) 80° (90°-10° and 89° (90°-1°), and in particular between) 82° (90°-8° and) 88° (90°-2°. According to one specific embodiment, the angle between the first surface 101 and the growth plane is 4°, so that the angle α between the first surface 101 and the first sidewall 110₁ of the trench 110 is 86°. There is a high charge carrier mobility in the SiC crystal along the 11-20 plane so that the alignment of the first sidewall to the c-axis results in a low resistance in the channel region along the electrical insulator 22 in the body region 13.

The gate trenches can be elongated trenches, wherein the gate electrodes 21 can be connected to a gate terminal electrode at positions that are out of view in the vertical cross-sectional view of FIG. 1B. The source electrode 41 covers the insulation layer 51 in those regions where the first contact openings 52 are located and is electrically connected to the contact regions 32 and the source regions 12 in the first contact openings 52.

A gate connection electrode (gate runner) 42 may be spaced apart from the source electrode 41 in the first lateral direction x and covers the insulation layer 51 in those regions where the second contact openings 52 are arranged. The gate connection electrode 42 is electrically connected to the gate electrodes 21 in the second contact openings 53.

In silicon carbide MOSFET devices charge trapping is a known issue, which may be caused by defects at the interface between the silicon carbide body and the electrical insulator that insulates the gate electrode from the silicon carbide body. Charge trapping may cause the electrical parameters of a silicon carbide device to drift during operation, which is not desirable. In particular, charge trapping may occur when carbon atoms are present in an interface layer between the silicon carbide body and an electrical insulator that insulates the gate electrode from the silicon carbide body. Typically, such an interface layer is formed by oxidizing (or oxynitriding) the silicon carbide body to silicon oxide (or silicon oxynitride) such as, for example, via annealing. Oxidizing (or oxynitriding) the silicon carbide body not only results in silicon oxide (silicon oxynitride), but also leaves carbon atoms that are incorporated in the silicon oxide (silicon oxynitride). The presence of these carbon atoms may be a cause for charge trapping. As such, reducing the amount of carbon atoms in the interface layer between the silicon carbide body and the electrical insulator that insulates the gate electrode may be desirable.

FIG. 1C illustrates a typical profile 10001 of a carbon concentration C within an interface layer 210 (with a thickness t) between a silicon carbide body 100 an electrical insulator 220 (such as electrical insulator 22 shown in FIGS. 1A and 1B) that insulates a gate electrode 21 from the interface layer 210 and/or from the silicon carbide body 100. Typically, due to the oxidizing (or oxynitriding) of the silicon carbide body, carbon atoms are incorporated in the interface layer 210. As such, a carbon concentration C along a cross-section through the silicon carbide body 100, the interface layer 210 and the electrical insulator 220 may be non-zero in the interface layer 210 and may typically decrease over the interface layer 210 (such as dropping from a first carbon concentration C1 at a first surface 301 of the interface layer 210 that is in contact with the silicon carbide body 100 to approximately zero within the electrical insulator 220. As discussed above, the presence of carbon atoms may cause charge trapping.

The first carbon concentration C1 at the first surface 301 may be approximately the same as the carbon concentration within the silicon carbide body 100 (which may be roughly 0.5). The carbon concentration C within the interface layer may then decrease to reach half of the first carbon concentration at a distance d1 from the first surface 301 (this point 10011 of the profile 10001 is indicated in FIG. 1C). Typical values for the distance d1 are 1 to 2 nm. In addition, the distance d1 is typically located approximately in the middle between the first surface 301 and the second surface 302 of the interface layer 210. In other words, the carbon concentration C is typically greater than half of the first carbon concentration C1 in approximately 50% of the interface layer 210 (i.e., the region from the first surface 301 to the distance d1) and smaller than the first carbon concentration in the remainder of the interface layer (i.e., from the first distance d1 to the second surface 302). That is to say, the distance d1 may be roughly half of the thickness t of the interface layer 210.

Methods according to present disclosure may allow to obtain an interface layer 210 with decreased amount of carbon in the interface layer 210, such as, for example, by depositing the interface layer 210 as further described below. This may avoid carbon atoms to be incorporated in the interface layer 210. However, still some carbon atoms may diffuse from the silicon carbide body 100 into the interface layer 210 (e.g., due to subsequent processing steps). As such, a profile of carbon concentration (when using the methods according to the present disclosure) may not necessarily show a sharp drop (such as a step) at the first surface 301 of the interface layer 210, but still some carbon atoms may be incorporated in the interface layer 210. This will be shown and discussed along FIGS. 1D and 1E. For example, the carbon concentration C may be smaller than half of the first carbon concentration C1 (C1 being at the first surface 301 of the interface layer 210) within more than 75% of the interface layer 210 or within more than 90% of the interface layer.

FIGS. 1D and 1E each illustrate a profile 1000₂, 1000₃ of a carbon concentration C within an interface layer 210 in accordance with the present disclosure. In some embodiments, the interface layer 210 is deposited on the (cleaned) silicon carbide surface of the silicon carbide body 100 via atomic layer deposition (ALD) or epitaxially. This may allow that less carbon atoms are incorporated in the interface layer 210 which may reduce charge trapping. According to the present disclosure, the interface layer 210 is disposed directly on the silicon carbide body 100 and arranged between the silicon carbide body 100 and an electrical insulator 220 that insulates a gate electrode 21 from the silicon carbide body 100 and/or from the interface layer 210. A thickness t of the interface layer may be less or equal to 15 nm. The interface layer may comprise a first surface 301 that is in contact with the silicon carbide body 100 and a second surface 302 that is opposing the first surface 301. A concentration of carbon within the interface layer 210 may decrease along a direction d that points from the first surface 301 to the second surface 302 from a first concentration C1 of carbon at the first surface 301 of the interface layer 210 to a second concentration C2 of carbon at a second surface 302 of the interface layer 210 opposing the first surface 301.

In an embodiment, the concentration of carbon C is less than half of the first concentration C1 within at least 75% of the interface layer 210, as indicated in FIG. 1D, where a point 1001₂ on the profile 1000₂. In other words, the distance d1 may be roughly 0.25 of thickness t of the interface layer 210.

In another embodiment, the concentration of carbon C is less than half of the first concentration C1 within at least 90% of the interface layer 210, as indicated in FIG. 1E, where a point 10013 on the profile 1000₃ In other words, the distance d1 may be roughly 0.1 of thickness t of the interface layer 210.

In both FIGS. 1D and 1E, the distance d1 from the first surface 301 to the point 1001₂ 1001₂ where the carbon concentration reaches half of the carbon concentration C1 that is present at the first surface 301 may be less than 1 nm.

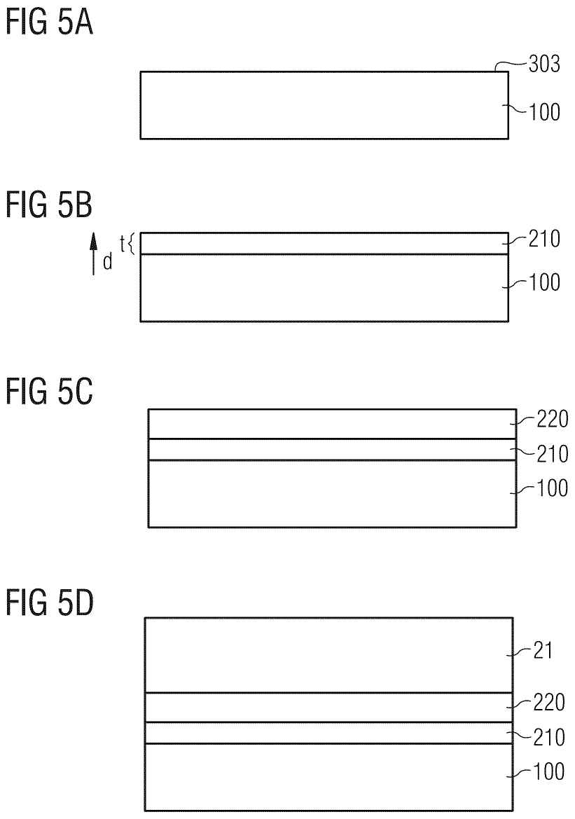

Referring to FIG. 2, according to the present disclosure, a silicon carbide device 1 (such as the silicon carbide device 1 shown in FIGS. 1A and 1B), which comprises a source region 12 of a first conductivity type formed in a silicon carbide body 100, a body region 13 of a second conductivity type formed in the silicon carbide body, a drain region 14, a gate electrode 21 configured to switch a current between the source region 12 and the drain region 14, includes an electrical insulator 22, 220 disposed between the gate electrode 21 and the silicon carbide body 100 and configured to electrically insulate the gate electrode 21 from the silicon carbide body 100. In addition, the silicon carbide device comprises an interface layer 210 disposed between the silicon carbide body 100 and the electrical insulator 220. The electrical insulator 220 may comprise or consist of a material that is different from the material of the interface layer 210. The interface layer 210 is in direct contact with the silicon carbide body 100. A thickness t of the interface layer 210 is less or equal to 15 nm (nanometer), in particular less or equal to 10 nm or 5 nm. In other examples, the interface layer 210 can have a thickness t of less or equal to 4 nm, 3 nm or 2 nm or may be a monolayer (i.e., a layer which consists only of one layer of atoms or molecules). For example, the interface layer 210 may consist of a material selected from the group consisting of silicon, aluminum nitride, titanium nitride, silicon nitride, aluminum oxide, zirconium oxide, hafnium oxide, gadolinium oxide, lanthanum oxide, silicon oxynitride, aluminum oxynitride, zirconium silicate, zirconium aluminum oxide, yttrium oxide, and aluminosilicate.

In addition, silicon carbide typically oxidizes to silicon oxide with carbon being incorporated in the silicon oxide. This may increase charge trapping, as compared to the case of silicon oxide without the carbon being incorporated. As such, oxidizing the silicon carbide to form silicon oxide as an electrical insulator may be prone to charge trapping. As such, according to the present disclosure, the interface layer 210 may consist of a material that comprises less carbon atoms as compared to a case when the silicon carbide is oxidized. In particular, according to the present disclosure, the material that forms the interface layer 210 may be deposited (such as via ALD or epitaxial growth).

More generally, according to the present disclosure the interface layer 210 may consist of a homogenous material or of an inhomogeneous material. For example, the interface layer 210 may consist of a material that comprises a first compound and a second compound, wherein a concentration of the first compound of the material decreases along a direction d that points from one surface 301 of the interface layer 210 (in contact with the silicon carbide body 100) to the other surface 302 of the interface layer 210, and a concentration of the second compound of the material increases along this direction d. In this example, the first compound may be selected from the group consisting of silicon, aluminum, titanium, zirconium, hafnium, gadolinium, and lanthanum, and the second compound may be selected from the group consisting of oxygen, nitrogen and oxynitride.

The electrical insulator 220 may consist of a material that is different from the material of the interface layer 210. For example, the electrical insulator 220 may consist of silicon oxide or a high-k material (such as aluminum nitride, titanium nitride, silicon nitride, aluminum oxide, zirconium oxide, hafnium oxide, silicon oxynitride, aluminosilicate, yttrium oxide, gadolinium oxide or lanthanum oxide). The electrical insulator 220 may have a thickness of 40 nm, 50 nm, 60 nm, 70 nm, 80 nm, 90 nm, 100 nm or even larger.

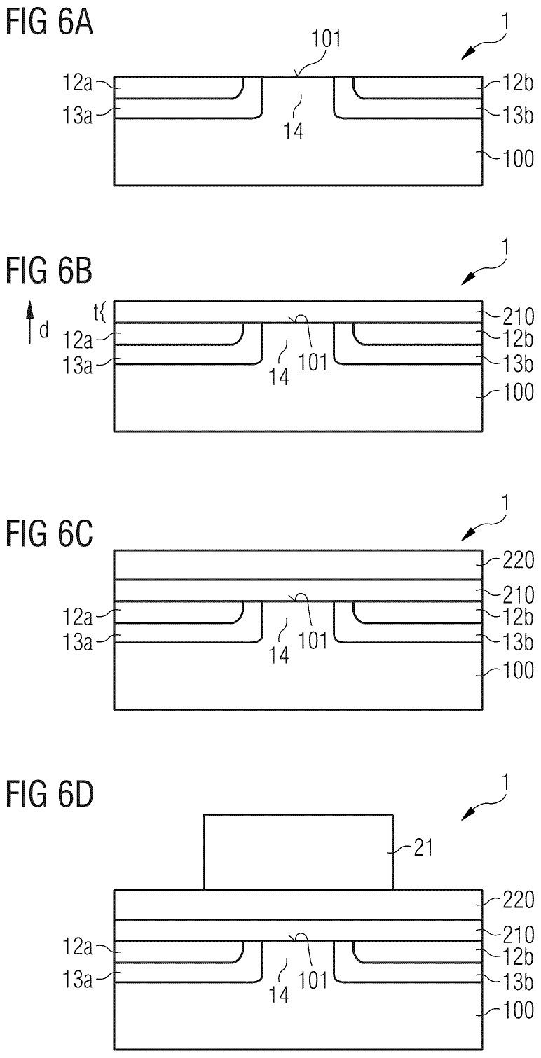

Still referring to FIG. 2, a cross-sectional view of an interface layer 210 and an electrical insulator 220 of a silicon carbide device 1 is shown that is arranged between the silicon carbide body 100 and the gate electrode 21. The electrical insulator 220, the silicon carbide body 100 and the gate electrode 21 of FIG. 2 may be correspond to the electrical insulator 22, silicon carbide body 100 and gate electrode 21 of FIGS. 1A and 1B. The remaining elements of FIGS. 1A and 1B are not shown in FIG. 2 for illustrative purposes. For example, the cross-section shown in FIG. 2 may be along the sidewalls 110₁, 110₂ and the bottom 110₃ of a gate trench as shown in FIG. 1B (or at least along a portion of the sidewalls or the bottom) or at a region where the gate electrode 21 is located above the electrical insulator 22 as shown in FIG. 1A. Generally, as shown in FIG. 2, a stack 2 may be formed by the gate electrode 21, the electrical insulator 220, the interface layer 210 and the silicon carbide body 100. In accordance with what has been discussed above regarding FIGS. 1A and 1B the gate electrode 21 may be configured to switch a current between the source region 11 and the drain region 14 of a silicon carbide device 1. The electrical insulator 220 is disposed between the gate electrode 21 and the silicon carbide body 100 of the silicon carbide device 1 and is configured to electrically insulate the gate electrode 22 from the silicon carbide body 100. The interface layer 210 is disposed between the silicon carbide body 100 and the electrical insulator 220. The electrical insulator 220 is disposed between the interface layer 210 and the gate electrode 21. Optionally, as discussed further below regarding FIG. 3, an additional layer may be disposed between the interface layer 210 and the electrical insulator 220. The interface layer 210 is in direct contact with the silicon carbide body 100. The thickness t of the interface layer 210 is less or equal to 15 nm and in particular less or equal than 10 nm or 5 nm. In other examples, the interface layer 210 can have a thickness of less or equal to 4 nm, 3 nm or 2 nm or may be a monolayer (i.e., a layer which consists only of one layer of atoms or molecules).

The following will describe several stacks 2 that are contemplated by the present disclosure. However, other stacks may also be contemplated so that the discussed stacks are not understood to be limiting the general concept of the present disclosure.

In a first embodiment the interface layer 210, being in direct contact with the silicon carbide body 100, consists of a material that comprises silicon nitride, and the electrical insulator 220, being in direct contact with the interface layer 210 and with the gate electrode 21, consists of a material that may comprise silicon oxide or a high-k material. Typical high-k materials are Al₂O₃, ZrO₂, HfO₂, AlN, alumisilicate AlSiOₓ, silicon doped HfO₂, TiO₂, Y₂O₃ and Si₃N₄. In one example, the material of the interface layer 210 may be homogenous (i.e., having the same or about the same concentration of silicon and the same or about the same concentration of nitrogen throughout the interface layer 210). In another example, the material of the interface layer 210 has a first concentration of nitrogen at the first surface 301 of the interface layer 210 (being in direct contact with the silicon carbide body 100) and a second concentration of nitrogen at the second surface 302 of the interface layer 210 (being in direct contact with the electrical insulator 220). Likewise, the material of the interface layer 210 has a first concentration of silicon at the first surface 301 of the interface layer 210 and a second concentration of silicon at the second surface 302 of the interface layer 210.

In one example, the concentration of nitrogen may decrease along a direction d that points from the first surface 301 (where the concentration of nitrogen is the first concentration of nitrogen) to the second surface 302 (where the concentration of nitrogen is the second concentration of nitrogen), and the concentration of silicon may increase along the direction d from being the first concentration of silicon (at the first surface 301) to being the second concentration of silicon (at the second surface 302). In other words, at the first surface 301 of the interface layer 210, the ratio of nitrogen to silicon may, for example, be 90:10 while the ratio of nitrogen to silicon at the second surface 302 may be one of 80:20, 70:30, 60:40, 50:50, 40:60, 30:70, 20:80, 10:90 or 0:100. Of course, another ratio of nitrogen to silicon may be present at the first surface 301, such as 100:0, 80:20, 70:30, and so on.

In another example of the first embodiment, within the interface layer 210, the concentration of nitrogen may increase from the first surface 301 to the second surface 302 along the direction d, while the concentration of silicon may decrease along the direction d. In other words, at the first surface 301 of the interface layer 210, the ratio of nitrogen to silicon may, for example, be 10:90 while the ratio of nitrogen to silicon at the second surface 302 may be one of 20:80, 30:70, 40:60, 50:50, 60:40, 70:30, 80:20, 90:10 or 100:0. Of course, another ratio of nitrogen to silicon may also be present at the first surface 301, such as 0:100, 20:80, 30:70, and so on.

As discussed above, the thickness t of the silicon nitride interface layer 210 is equal to or less than 15 nm, and in particular equal to or less than 10 nm or 5 nm. For example, the thickness t of the interface layer 210 may be less than or equal to 4 nm, 3 nm or 2 nm or may be a monolayer (i.e., a layer which consists only of one layer of atoms or molecules).

In a second embodiment the interface layer 210, being in direct contact with the silicon carbide body 100, consists of a material that comprises silicon oxynitride, and the electrical insulator 220, being in direct contact with the interface layer 210 and with the gate electrode 21, consists of a material that comprises silicon oxide or a high-k material. In one example, the material of the interface layer 210 may be homogenous (i.e., having the same or about the same concentration of silicon, the same or about the same concentration of oxygen, and the same or about the same concentration of nitrogen throughout the interface layer 210). In another example, the material of the interface layer 210 has a first concentration of nitrogen at the first surface 301 of the interface layer 210 (being in direct contact with the silicon carbide body 100) and a second concentration of nitrogen at the second surface 302 of the interface layer 210 (being in direct contact with the electrical insulator 220). Likewise, the material of the interface layer 210 may have a first concentration of silicon at the first surface 301 of the interface layer 210 and a second concentration of silicon at the second surface 302 of the interface layer 210, as well as a first concentration of oxygen at the first surface 301 and a second concentration of oxygen at the second surface 302.

In one example, the concentration of silicon may decrease along a direction d that points from the first surface 301 (where the concentration of silicon is the first concentration of silicon) to the second surface 302 (where the concentration of silicon is the second concentration of silicon), and the concentrations of oxygen and nitrogen may increase along the direction d from being the first concentration of oxygen and the first concentration of nitrogen (at the first surface 301) to being the second concentration of oxygen and the second concentration of nitrogen (at the second surface 302). In other words, at the first surface 301 of the interface layer 210, the ratio of silicon to oxygen plus nitrogen may, for example, be 90:10 while the ratio of silicon to oxygen plus nitrogen at the second surface 302 may be one of 80:20, 70:30, 60:40, 50:50, 40:60, 30:70, 20:80, 10:90 or 0:100. Of course, another ratio of silicon to oxygen plus nitrogen may be present at the first surface 301, such as 100:0, 80:20, 70:30, and so on.

In another example, such as, for example, of the second embodiment, within the interface layer 210, the concentration of silicon may increase from the first surface 301 to the second surface 302 along the direction d, while the concentrations of nitrogen and oxygen may decrease. In other words, at the first surface 301 of the interface layer 210, the ratio of silicon to oxygen plus nitrogen may, for example, be 10:90 while the ratio of silicon to oxygen plus nitrogen at the second surface 302 may be one of 20:80, 30:70, 40:60, 50:50, 60:40, 70:30, 80:20, 90:10 or 100:0. Of course, another ration of silicon to oxygen plus nitrogen may also be present at the first surface 301, such as 0:100, 20:80, 30:70, and so on.

In addition to that, also the ratio of oxygen to nitrogen may increase or decrease, for example from being 10:90 at the first surface 301 to being 90:10 at the second surface 302 (or vice versa).

As discussed above, the thickness t of the silicon oxynitride interface layer 210 is equal to or less than 15 nm, and in particular equal to or less than 10 nm or 5 nm. For example, the thickness t of the interface layer 210 may be less than or equal to 4 nm, 3 nm or 2 nm or may be a monolayer (i.e., a layer which consists only of one layer of atoms or molecules).

In a third embodiment the interface layer 210, being in direct contact with the silicon carbide body 100, consists of a material that comprises aluminum nitride, and the electrical insulator 220, being in direct contact with the interface layer 210 and with the gate electrode 21, consists of a material that comprises silicon oxide or a high-k material. In one example, the material of the interface layer 210 may be homogenous (i.e., having the same or about the same concentration of aluminum and the same or about the same concentration of nitrogen throughout the interface layer 210). In another example, the material of the interface layer 210 has a first concentration of nitrogen at the first surface 301 of the interface layer 210 (being in direct contact with the silicon carbide body 100) and a second concentration of nitrogen at the second surface 302 of the interface layer 210 (being in direct contact with the electrical insulator 220). Likewise, the material of the interface layer 210 may have a first concentration of aluminum at the first surface 301 of the interface layer 210 and a second concentration of aluminum at the second surface 302 of the interface layer 210.

In one example, the concentration of nitrogen may decrease along a direction d that points from the first surface 301 (where the concentration of nitrogen is the first concentration of nitrogen) to the second surface 302 (where the concentration of nitrogen is the second concentration of nitrogen), and the concentration of aluminum may increase along the direction d from being the first concentration of aluminum (at the first surface 301) to being the second concentration of aluminum (at the second surface 302). In other words, at the first surface 301 of the interface layer 210, the ratio of nitrogen to aluminum may, for example, be 90:10 while the ratio of nitrogen to aluminum at the second surface 302 may be one of 80:20, 70:30, 60:40, 50:50, 40:60, 30:70, 20:80, 10:90 or 0:100. Of course, another ration of nitrogen to aluminum may be present at the first surface 301, such as 100:0, 80:20, 70:30, and so on.

In another example, such as, for example, of the third embodiment, within the interface layer 210, the concentration of nitrogen may increase from the first surface 301 to the second surface 302 along the direction d, while the concentration of aluminum may decrease along the direction d. In other words, at the first surface 301 of the interface layer 210, the ratio of nitrogen to aluminum may, for example, be 10:90 while the ratio of nitrogen to aluminum at the second surface 302 may be one of 20:80, 30:70, 40:60, 50:50, 60:40, 70:30, 80:20, 90:10 or 100:0.

As discussed above, the thickness t of the aluminum nitride interface layer 210 is equal to or less than 15 nm, and in particular equal to or less than 10 nm or 5 nm. For example, the thickness t of the interface layer 210 may be less than or equal to 4 nm, 3 nm or 2 nm or may be a monolayer (i.e., a layer which consists only of one layer of atoms or molecules).

In a fourth embodiment the interface layer 210, being in direct contact with the silicon carbide body 100, consists of a material that comprises aluminum oxynitride, and the electrical insulator 220, being in direct contact with the interface layer 210 and with the gate electrode 21, consists of a material that comprises silicon oxide or a high-k material. In one example, the material of the interface layer 210 may be homogenous (i.e., having the same or about the same concentration of aluminum, the same or about the same concentration of oxygen, and the same or about the same concentration of nitrogen throughout the interface layer 210). In another example, the material of the interface layer 210 has a first concentration of nitrogen at the first surface 301 of the interface layer 210 (being in direct contact with the silicon carbide body 100) and a second concentration of nitrogen at the second surface 302 of the interface layer 210 (being in direct contact with the electrical insulator 220). Likewise, the material of the interface layer 210 has a first concentration of aluminum at the first surface 301 of the interface layer 210 and a second concentration of aluminum at the second surface 302 of the interface layer 210, as well as a first concentration of oxygen at the first surface 301 and a second concentration of oxygen at the second surface 302.

In one example, the concentration of aluminum may decrease along a direction d that points from the first surface 301 (where the concentration of aluminum is the first concentration of aluminum) to the second surface 302 (where the concentration of aluminum is the second concentration of aluminum), and the concentrations of oxygen and nitrogen may increase along the direction d from being the first concentration of oxygen and the first concentration of nitrogen (at the first surface 301) to being the second concentration of oxygen and the second concentration of nitrogen (at the second surface 302). In other words, at the first surface 301 of the interface layer 210, the ratio of aluminum to oxygen plus nitrogen may, for example, be 90:10 while the ratio of aluminum to oxygen plus nitrogen at the second surface 302 may be one of 80:20, 70:30, 60:40, 50:50, 40:60, 30:70, 20:80, 10:90 or 0:100. Of course, another ratio of aluminum to oxygen plus nitrogen may be present at the first surface 301, such as 100:0, 80:20, 70:30, and so on.

In another example, such as, for example, of the fourth embodiment, within the interface layer 210, the concentration of aluminum may increase from the first surface 301 to the second surface 302 along the direction d, while the concentrations of nitrogen and oxygen may decrease. In other words, at the first surface 301 of the interface layer 210, the ratio of aluminum to oxygen plus nitrogen may, for example, be 10:90 while the ratio of aluminum to oxygen plus nitrogen at the second surface 302 may be one of 20:80, 30:70, 40:60, 50:50, 60:40, 70:30, 80:20, 90:10 or 100:0. Of course, another ration of aluminum to oxygen plus nitrogen may also be present at the first surface 301, such as 0:100, 20:80, 30:70, and so on.

In addition to that, also the ration of oxygen to nitrogen may increase or decrease, for example from being 10:90 at the first surface 301 to being 90:10 at the second surface 302 (or vice versa).

As discussed above, the thickness t of the aluminum oxynitride interface layer 210 is equal to or less than 15 nm, and in particular equal to or less than 10 nm or 5 nm. For example, the thickness t of the interface layer 210 may be less than or equal to 4 nm, 3 nm or 2 nm or may be a monolayer (i.e., a layer which consists only of one layer of atoms or molecules).

In a fifth embodiment the interface layer 210, being in direct contact with the silicon carbide body 100, consists of a material that comprises titanium nitride, and the electrical insulator 220, being in direct contact with the interface layer 210 and with the gate electrode 21, consists of a material that comprises of silicon oxide or a high-k material. In one example, the material of the interface layer 210 may be homogenous (i.e., having the same or about the same concentration of titanium and the same or about the same concentration of nitrogen throughout the interface layer 210). In another example, the material of the interface layer 210 has a first concentration of nitrogen at the first surface 301 of the interface layer 210 (being in direct contact with the silicon carbide body 100) and a second concentration of nitrogen at the second surface 302 of the interface layer 210 (being in direct contact with the electrical insulator 220). Likewise, the material of the interface layer 210 has a first concentration of titanium at the first surface 301 of the interface layer 210 and a second concentration of titanium at the second surface 302 of the interface layer 210.

In one example, the concentration of nitrogen may decrease along a direction d that points from the first surface 301 (where the concentration of nitrogen is the first concentration of nitrogen) to the second surface 302 (where the concentration of nitrogen is the second concentration of nitrogen), and the concentration of titanium may increase along the direction d from being the first concentration of titanium (at the first surface 301) to being the second concentration of titanium (at the second surface 302). In other words, at the first surface 301 of the interface layer 210, the ratio of nitrogen to titanium may, for example, be 90:10 while the ratio of nitrogen to titanium at the second surface 302 may be one of 80:20, 70:30, 60:40, 50:50, 40:60, 30:70, 20:80, 10:90 or 0:100. Of course, another ration of nitrogen to titanium may be present at the first surface 301, such as 100:0, 80:20, 70:30, and so on.

In another example, such as, for example, of the fifth embodiment, within the interface layer 210, the concentration of nitrogen may increase from the first surface 301 to the second surface 302 along the direction d, while the concentration of titanium may decrease along the direction d. In other words, at the first surface 301 of the interface layer 210, the ratio of nitrogen to titanium may, for example, be 10:90 while the ratio of nitrogen to titanium at the second surface 302 may be one of 20:80, 30:70, 40:60, 50:50, 60:40, 70:30, 80:20, 90:10 or 100:0. Of course, another ration of nitrogen to titanium may also be present at the first surface 301, such as 0:100, 20:80, 30:70, and so on.

As discussed above, the thickness t of the titanium nitride interface layer 210 is equal to or less than 15 nm, and in particular equal to or less than 10 nm or 5 nm. For example, the thickness t of the interface layer 210 may be less than or equal to 4 nm, 3 nm or 2 nm or may be a monolayer (i.e., a layer which consists only of one layer of atoms or molecules).

In a sixth embodiment the interface layer 210, being in direct contact with the silicon carbide body 100, consists of a material that comprises of zirconium oxide, and the electrical insulator 220, being in direct contact with the interface layer 210 and with the gate electrode 21, consists of a material that comprises silicon oxide or a high-k material. In one example, the material of the interface layer 210 may be homogenous (i.e., having the same or about the same concentration of zirconium and the same or about the same concentration of oxygen throughout the interface layer 210). In another example, the material of the interface layer 210 has a first concentration of zirconium at the first surface 301 of the interface layer 210 (being in direct contact with the silicon carbide body 100) and a second concentration of zirconium at the second surface 302 of the interface layer 210 (being in direct contact with the electrical insulator 220). Likewise, the material of the interface layer 210 has a first concentration of oxygen at the first surface 301 of the interface layer 210 and a second concentration of oxygen at the second surface 302 of the interface layer 210.

In one example, the concentration of zirconium may decrease along a direction d that points from the first surface 301 (where the concentration of zirconium is the first concentration of zirconium) to the second surface 302 (where the concentration of zirconium is the second concentration of zirconium), and the concentration of oxygen may increase along the direction d from being the first concentration of oxygen (at the first surface 301) to being the second concentration of oxygen (at the second surface 302). In other words, at the first surface 301 of the interface layer 210, the ratio of zirconium to oxygen may, for example, be 90:10 while the ratio of zirconium to oxygen at the second surface 302 may be one of 80:20, 70:30, 60:40, 50:50, 40:60, 30:70, 20:80, 10:90 or 0:100. Of course, another ration of zirconium to oxygen may be present at the first surface 301, such as 100:0, 80:20, 70:30, and so on.

In another example, such as, for example, of the sixth embodiment, within the interface layer 210, the concentration of zirconium may increase from the first surface 301 to the second surface 302 along the direction d, while the concentration of oxygen may decrease along the direction d. In other words, at the first surface 301 of the interface layer 210, the ratio of zirconium to oxygen may, for example, be 10:90 while the ratio of zirconium to oxygen at the second surface 302 may be one of 20:80, 30:70, 40:60, 50:50, 60:40, 70:30, 80:20, 90:10 or 100:0. Of course, another ration of zirconium to oxygen may also be present at the first surface 301, such as 0:100, 20:80, 30:70, and so on.

As discussed above, the thickness t of the zirconium oxide interface layer 210 is equal to or less than 15 nm, and in particular equal to or less than 10 nm or 5 nm. For example, the thickness t of the interface layer 210 may be less than or equal to 4 nm, 3 nm or 2 nm or may be a monolayer (i.e., a layer which consists only of one layer of atoms or molecules).

In a seventh embodiment the interface layer 210, being in direct contact with the silicon carbide body 100, consists of a material that comprises hafnium oxide, and the electrical insulator, being in direct contact with the interface layer 210 and with the gate electrode 21, consists of a material that comprises silicon oxide or a high-k material. In one example, the material of the interface layer 210 may be homogenous (i.e., having the same or about the same concentration of hafnium and the same or about the same concentration of oxygen throughout the interface layer 210). In another example, the material of the interface layer 210 has a first concentration of hafnium at the first surface 301 of the interface layer 210 (being in direct contact with the silicon carbide body 100) and a second concentration of hafnium at the second surface 302 of the interface layer 210 (being in direct contact with the electrical insulator 220). Likewise, the material of the interface layer 210 has a first concentration of oxygen at the first surface 301 of the interface layer 210 and a second concentration of oxygen at the second surface 302 of the interface layer 210.

In one example, the concentration of hafnium may decrease along a direction d that points from the first surface 301 (where the concentration of hafnium is the first concentration of hafnium) to the second surface 302 (where the concentration of hafnium is the second concentration of hafnium), and the concentration of oxygen may increase along the direction d from being the first concentration of oxygen (at the first surface 301) to being the second concentration of oxygen (at the second surface 302). In other words, at the first surface 301 of the interface layer 210, the ratio of hafnium to oxygen may, for example, be 90:10 while the ratio of hafnium to oxygen at the second surface 302 may be one of 80:20, 70:30, 60:40, 50:50, 40:60, 30:70, 20:80, 10:90 or 0:100. Of course, another ration of hafnium to oxygen may be present at the first surface 301, such as 100:0, 80:20, 70:30, and so on.

In another example, such as, for example, of the seventh embodiment, within the interface layer 210, the concentration of hafnium may increase from the first surface 301 to the second surface 302 along the direction d, while the concentration of oxygen may decrease along the direction d. In other words, at the first surface 301 of the interface layer 210, the ratio of hafnium to oxygen may, for example, be 10:90 while the ratio of hafnium to oxygen at the second surface 302 may be one of 20:80, 30:70, 40:60, 50:50, 60:40, 70:30, 80:20, 90:10 or 100:0. Of course, another ration of hafnium to oxygen may also be present at the first surface 301, such as 0:100, 20:80, 30:70, and so on.

As discussed above, the thickness t of the hafnium oxide interface layer 210 is equal to or less than 10 nm, and in particular equal to or less than 5 nm. For example, the thickness t of the interface layer 210 may be less than or equal to 4 nm, 3 nm or 2 nm or may be a monolayer (i.e., a layer which consists only of one layer of atoms or molecules).

In an eighth embodiment the interface layer 210, being in direct contact with the silicon carbide body 100, consists of a material that comprises of gadolinium oxide, and the electrical insulator 220, being in direct contact with the interface layer 210 and with the gate electrode 21, consists of a material that comprises silicon oxide or a high-k material. In one example, the material of the interface layer 210 may be homogenous (i.e., having the same or about the same concentration of gadolinium and the same or about the same concentration of oxygen throughout the interface layer 210). In another example, the material of the interface layer 210 has a first concentration of gadolinium at the first surface 301 of the interface layer 210 (being in direct contact with the silicon carbide body 100) and a second concentration of gadolinium at the second surface 302 of the interface layer 210 (being in direct contact with the electrical insulator 220). Likewise, the material of the interface layer 210 has a first concentration of oxygen at the first surface 301 of the interface layer 210 and a second concentration of oxygen at the second surface 302 of the interface layer 210.

In one example, the concentration of gadolinium may decrease along a direction d that points from the first surface 301 (where the concentration of gadolinium is the first concentration of gadolinium) to the second surface 302 (where the concentration of gadolinium is the second concentration of gadolinium), and the concentration of oxygen may increase along the direction d from being the first concentration of oxygen (at the first surface 301) to being the second concentration of oxygen (at the second surface 302). In other words, at the first surface 301 of the interface layer 210, the ratio of gadolinium to oxygen may, for example, be 90:10 while the ratio of gadolinium to oxygen at the second surface 302 may be one of 80:20, 70:30, 60:40, 50:50, 40:60, 30:70, 20:80, 10:90 or 0:100. Of course, another ration of gadolinium to oxygen may be present at the first surface 301, such as 100:0, 80:20, 70:30, and so on.

In another example, such as, for example, of the eight embodiment, within the interface layer 210, the concentration of gadolinium may increase from the first surface 301 to the second surface 302 along the direction d, while the concentration of oxygen may decrease along the direction d. In other words, at the first surface 301 of the interface layer 210, the ratio of gadolinium to oxygen may, for example, be 10:90 while the ratio of gadolinium to oxygen at the second surface 302 may be one of 20:80, 30:70, 40:60, 50:50, 60:40, 70:30, 80:20, 90:10 or 100:0. Of course, another ration of gadolinium to oxygen may also be present at the first surface 301, such as 0:100, 20:80, 30:70, and so on.

As discussed above, the thickness t of the gadolinium oxide interface layer 210 is equal to or less than 15 nm, and in particular equal to or less than 10 nm or 5 nm. For example, the thickness t of the interface layer 210 may be less than or equal to 4 nm, 3 nm or 2 nm or may be a monolayer (i.e., a layer which consists only of one layer of atoms or molecules).

In a ninth embodiment the interface layer 210, being in direct contact with the silicon carbide body 100, consists of a material that comprises lanthanum oxide, and the electrical insulator 220, being in direct contact with the interface layer 210 and with the gate electrode 21, consists of a material that comprises silicon oxide or a high-k material. In one example, the material of the interface layer 210 may be homogenous (i.e., having the same or about the same concentration of lanthanum and the same or about the same concentration of oxygen throughout the interface layer 210). In another example, the material of the interface layer 210 has a first concentration of lanthanum at the first surface 301 of the interface layer 210 (being in direct contact with the silicon carbide body 100) and a second concentration of lanthanum at the second surface 302 of the interface layer 210 (being in direct contact with the electrical insulator 220). Likewise, the material of the interface layer 210 has a first concentration of oxygen at the first surface 301 of the interface layer 210 and a second concentration of oxygen at the second surface 302 of the interface layer 210.

In one example, the concentration of lanthanum may decrease along a direction d that points from the first surface 301 (where the concentration of lanthanum is the first concentration of lanthanum) to the second surface 302 (where the concentration of lanthanum is the second concentration of lanthanum), and the concentration of oxygen may increase along the direction d from being the first concentration of oxygen (at the first surface 301) to being the second concentration of oxygen (at the second surface 302). In other words, at the first surface 301 of the interface layer 210, the ratio of lanthanum to oxygen may, for example, be 90:10 while the ratio of lanthanum to oxygen at the second surface 302 may be one of 80:20, 70:30, 60:40, 50:50, 40:60, 30:70, 20:80, 10:90 or 0:100. Of course, another ration of lanthanum to oxygen may be present at the first surface 301, such as 100:0, 80:20, 70:30, and so on.

In another example, such as, for example, of the ninth embodiment, within the interface layer 210, the concentration of lanthanum may increase from the first surface 301 to the second surface 302 along the direction d, while the concentration of oxygen may decrease along the direction d. In other words, at the first surface 301 of the interface layer 210, the ratio of lanthanum to oxygen may, for example, be 10:90 while the ratio of lanthanum to oxygen at the second surface 302 may be one of 20:80, 30:70, 40:60, 50:50, 60:40, 70:30, 80:20, 90:10 or 100:0. Of course, another ration of lanthanum to oxygen may also be present at the first surface 301, such as 0:100, 20:80, 30:70, and so on.

As discussed above, the thickness t of the lanthanum oxide interface layer 210 is equal to or less than 15 nm, and in particular equal to or less than 10 nm or 5 nm. For example, the thickness t of the interface layer 210 may be less than or equal to 4 nm, 3 nm or 2 nm or may be a monolayer (i.e., a layer which consists only of one layer of atoms or molecules).

In a tenth embodiment the interface layer 210, being in direct contact with the silicon carbide body 100, consists of a material that comprises aluminum oxide, and the electrical insulator 220, being in direct contact with the interface layer 210 and with the gate electrode 21, consists of a material that comprises silicon oxide or a high-k material. In one example, the material of the interface layer 210 may be homogenous (i.e., having the same or about the same concentration of aluminum and the same or about the same concentration of oxygen throughout the interface layer 210). In another example, the material of the interface layer 210 has a first concentration of aluminum at the first surface 301 of the interface layer 210 (being in direct contact with the silicon carbide body 100) and a second concentration of aluminum at the second surface 302 of the interface layer 210 (being in direct contact with the electrical insulator 220). Likewise, the material of the interface layer 210 has a first concentration of oxygen at the first surface 301 of the interface layer 210 and a second concentration of oxygen at the second surface 302 of the interface layer 210.

In one example, the concentration of aluminum may decrease along a direction d that points from the first surface 301 (where the concentration of aluminum is the first concentration of aluminum) to the second surface 302 (where the concentration of aluminum is the second concentration of aluminum), and the concentration of oxygen may increase along the direction d from being the first concentration of oxygen (at the first surface 301) to being the second concentration of oxygen (at the second surface 302). In other words, at the first surface 301 of the interface layer 210, the ratio of aluminum to oxygen may, for example, be 90:10 while the ratio of aluminum to oxygen at the second surface 302 may be one of 80:20, 70:30, 60:40, 50:50, 40:60, 30:70, 20:80, 10:90 or 0:100. Of course, another ration of aluminum to oxygen may be present at the first surface 301, such as 100:0, 80:20, 70:30, and so on.

In another example, such as, for example, of the tenth embodiment, within the interface layer 210, the concentration of aluminum may increase from the first surface 301 to the second surface 302 along the direction d, while the concentration of oxygen may decrease along the direction d. In other words, at the first surface 301 of the interface layer 210, the ratio of aluminum to oxygen may, for example, be 10:90 while the ratio of aluminum to oxygen at the second surface 302 may be one of 20:80, 30:70, 40:60, 50:50, 60:40, 70:30, 80:20, 90:10 or 100:0. Of course, another ration of aluminum to oxygen may also be present at the first surface 301, such as 0:100, 20:80, 30:70, and so on.

As discussed above, the thickness t of the aluminum oxide interface layer 210 is equal to or less than 15 nm, and in particular equal to or less than 10 nm or 5 nm. For example, the thickness t of the interface layer 210 may be less than or equal to 4 nm, 3 nm or 2 nm or may be a monolayer (i.e., a layer which consists only of one layer of atoms or molecules).

In an eleventh embodiment the interface layer 210, being in direct contact with the silicon carbide body 100, consists of a material that comprises silicon oxide, and the electrical insulator 220, being in direct contact with the interface layer 210 and with the gate electrode 21, consists of a material that comprises silicon oxide or a high-k material. In one example, the material of the interface layer 210 may be homogenous (i.e., having the same or about the same concentration of silicon and the same or about the same concentration of oxygen throughout the interface layer 210). In another example, the material of the interface layer 210 has a first concentration of silicon at the first surface 301 of the interface layer 210 (being in direct contact with the silicon carbide body 100) and a second concentration of silicon at the second surface 302 of the interface layer 210 (being in direct contact with the electrical insulator 220). Likewise, the material of the interface layer 210 has a first concentration of oxygen at the first surface 301 of the interface layer 210 and a second concentration of oxygen at the second surface 302 of the interface layer 210.

In one example, the concentration of silicon may decrease along a direction d that points from the first surface 301 (where the concentration of silicon is the first concentration of silicon) to the second surface 302 (where the concentration of silicon is the second concentration of silicon), and the concentration of oxygen may increase along the direction d from being the first concentration of oxygen (at the first surface 301) to being the second concentration of oxygen (at the second surface 302). In other words, at the first surface 301 of the interface layer 210, the ratio of silicon to oxygen may, for example, be 90:10 while the ratio of silicon to oxygen at the second surface 302 may be one of 80:20, 70:30, 60:40, 50:50, 40:60, 30:70, 20:80, 10:90 or 0:100. Of course, another ration of silicon to oxygen may be present at the first surface 301, such as 100:0, 80:20, 70:30, and so on.

In another example, such as, for example, of the eleventh embodiment, within the interface layer 210, the concentration of silicon may increase from the first surface 301 to the second surface 302 along the direction d, while the concentration of oxygen may decrease along the direction d. In other words, at the first surface 301 of the interface layer 210, the ratio of silicon to oxygen may, for example, be 10:90 while the ratio of silicon to oxygen at the second surface 302 may be one of 20:80, 30:70, 40:60, 50:50, 60:40, 70:30, 80:20, 90:10 or 100:0. Of course, another ration of silicon to oxygen may also be present at the first surface 301, such as 0:100, 20:80, 30:70, and so on.

As discussed above, the thickness t of the silicon oxide interface layer 210 is equal to or less than 15 nm, and in particular equal to or less than 10 nm or 5 nm. For example, the thickness t of the interface layer 210 may be less than or equal to 4 nm, 3 nm or 2 nm or may be a monolayer (i.e., a layer which consists only of one layer of atoms or molecules).

In a twelfth embodiment the interface layer 210, being in direct contact with the silicon carbide body 100, consists of a material that comprises zirconium aluminum oxide, and the electrical insulator 220, being in direct contact with the interface layer 210 and with the gate electrode 21, consists of a material that comprises silicon oxide or a high-k material. In one example, the material of the interface layer 210 may be homogenous (i.e., having the same or about the same concentration of zirconium, the same or about the same concentration of aluminum, and the same or about the same concentration of oxygen throughout the interface layer 210). In another example, the material of the interface layer 210 has a first concentration of zirconium at the first surface 301 of the interface layer 210 (being in direct contact with the silicon carbide body 100) and a second concentration of zirconium at the second surface 302 of the interface layer 210 (being in direct contact with the electrical insulator 220). Likewise, the material of the interface layer 210 has first concentrations of aluminum and oxygen at the first surface 301 of the interface layer 210 and second concentrations of aluminum and oxygen at the second surface 302 of the interface layer 210.

Again, some of the concentrations of zirconium, aluminum and oxide may increase while the remaining concentrations of zirconium, aluminum and oxide may decrease along the direction d. For example, a ration of zirconium to aluminum to oxide could be 60:30:10 at the first surface 301 and 10:30:60 at the second surface 302 of the interface layer 210. Of course, other rations at the first and second surfaces 301, 302 are possible and contemplated by the present disclosure.

As discussed above, the thickness t of the zirconium aluminum oxide interface layer 210 is equal to or less than 15 nm, and in particular equal to or less than 10 nm or 5 nm. For example, the thickness t of the interface layer 210 may be less than or equal to 4 nm, 3 nm or 2 nm or may be a monolayer (i.e., a layer which consists only of one layer of atoms or molecules).

In a thirteenth embodiment the interface layer 210, being in direct contact with the silicon carbide body 100, consists of a material that comprises zirconium silicate, and the electrical insulator 220, being in direct contact with the interface layer 210 and with the gate electrode 21, consists of a material that comprises silicon oxide or a high-k material. In one example, the material of the interface layer 210 may be homogenous (i.e., having the same or about the same concentration of zirconium, the same or about the same concentration of silicon, and the same or about the same concentration of oxygen throughout the interface layer 210). In another example, the material of the interface layer 210 has a first concentration of zirconium at the first surface 301 of the interface layer 210 (being in direct contact with the silicon carbide body 100) and a second concentration of zirconium at the second surface 302 of the interface layer 210 (being in direct contact with the electrical insulator 220). Likewise, the material of the interface layer 210 has first concentrations of silicon and oxygen at the first surface 301 of the interface layer 210 and second concentrations of silicon and oxygen at the second surface 302 of the interface layer 210.

Again, some of the concentrations of zirconium, silicon and oxide may increase while the remaining concentrations of zirconium, silicon and oxide may decrease along the direction d. For example, a ration of zirconium to silicon to oxide could be 60:30:10 at the first surface 301 and 10:30:60 at the second surface 302 of the interface layer 210. Of course, other ratios at the first and second surfaces 301, 302 are possible and contemplated by the present disclosure.

As discussed above, the thickness t of the zirconium silicate interface layer 210 is equal to or less than 15 nm, and in particular equal to or less than 10 nm or 5 nm. For example, the thickness t of the interface layer 210 may be less than or equal to 4 nm, 3 nm or 2 nm or may be a monolayer (i.e., a layer which consists only of one layer of atoms or molecules).

In a fourteenth embodiment the interface layer 210, being in direct contact with the silicon carbide body 100, consists of a material that comprises aluminum silicate, and the electrical insulator 220, being in direct contact with the interface layer 210 and with the gate electrode 21, consists of a material that comprises silicon oxide or a high-k material. In one example, the material of the interface layer 210 may be homogenous (i.e., having the same or about the same concentration of aluminum, the same or about the same concentration of silicon, and the same or about the same concentration of oxygen throughout the interface layer 210). In another example, the material of the interface layer 210 has a first concentration of aluminum at the first surface 301 of the interface layer 210 (being in direct contact with the silicon carbide body 100) and a second concentration of aluminum at the second surface 302 of the interface layer 210 (being in direct contact with the electrical insulator 220). Likewise, the material of the interface layer 210 has first concentrations of silicon and oxygen at the first surface 301 of the interface layer 210 and second concentrations of silicon and oxygen at the second surface 302 of the interface layer 210.

Again, some of the concentrations of aluminum, silicon and oxide may increase while the remaining concentrations of aluminum, silicon and oxide may decrease along the direction d. For example, a ration of aluminum to silicon to oxide could be 60:30:10 at the first surface 301 and 10:30:60 at the second surface 302 of the interface layer 210. Of course, other rations at the first and second surfaces 301, 302 are possible and contemplated by the present disclosure.

As discussed above, the thickness t of the aluminum silicate interface layer 210 is equal to or less than 15 nm, and in particular equal to or less than 10 nm or 5 nm. For example, the thickness t of the interface layer 210 may be less than or equal to 4 nm, 3 nm or 2 nm or may be a monolayer (i.e., a layer which consists only of one layer of atoms or molecules).

In a fifteenth embodiment the interface layer 210, being in direct contact with the silicon carbide body 100, consists of a material that comprises silicon, and the electrical insulator 220, being in direct contact with the interface layer 210 and with the gate electrode 21, consists of a material that comprises of silicon oxide or a high-k material. The material of the interface layer 210 may comprise at least one of monocrystalline silicon, polycrystalline silicon and amorphous silicon.

As discussed above, the thickness t of the silicon interface layer 210 may be equal to or less than 15 nm, and in particular equal to or less than 10 nm or 5 nm. For example, the thickness t of the interface layer 210 may be less than or equal to 4 nm, 3 nm or 2 nm or may be a monolayer (i.e., a layer which consists only of one layer of atoms or molecules).

In case the material of the interface layer 210 comprises or consists of monocrystalline silicon, the layer may be thin enough so that the layer does not relax due to the lattice mismatch with the silicon carbide.

In addition to the above-discussed stacks 2, also stacks 2 where the interface layer 210 may consist of a material that comprises of hafnium oxide, titanium oxide, tantalum oxide, yttrium oxide or mixture with Al or Si of such oxides. As described above in more detail the concentration of the compounds may vary from the first surface 301 of the interface layer 210 to the second surface 302 of the interface layer 210.

Referring to FIG. 3, a cross-sectional view of a silicon carbide device 1 is shown that comprises the silicon carbide body 100, the interface layer 210, the electrical insulator 220 and the gate electrode 21. The electrical insulator 220, silicon carbide body 100 and gate electrode 21 of FIG. 3 may be correspond to the electrical insulator 22, 220, silicon carbide body 100 and gate electrode 21, respectively of FIGS. 1A, 1B, and 2. The difference between FIGS. 2 and 3 is that the electrical insulator 22 not only comprises the interface layer 210 and the electrical insulator 220, but also an additional layer 230 disposed between the interface layer 210 and the electrical insulator 220 of the electrical insulator 22. The remaining elements of FIGS. 1A and 1B are not shown in FIG. 3 for illustrative purposes. For example, the cross-section shown in FIG. 3 may be along the sidewalls 110₁, 110₂ and the bottom 110₃ of a gate trench as shown in FIG. 1B (or at least along a portion of the sidewalls or the bottom) or at a region where the gate electrode 21 is located above the electrical insulator 22 as shown in FIG. 1A. Generally, as shown in FIG. 3, a stack 2 may be formed by the gate electrode 21, the electrical insulator 220, the additional layer 230, the interface layer 210, and the silicon carbide body 100. In accordance with what has been discussed above regarding FIGS. 1A, 1B, and 2, the gate electrode 21 may be configured to switch a current between the source region 11 and the drain region 14 of a silicon carbide device 1. The electrical insulator 220 is disposed between the gate electrode 21 and the silicon carbide body 100 of the silicon carbide device 1 and configured to electrically insulate the gate electrode 21 from the silicon carbide body 100. The interface layer 210 is disposed between the silicon carbide body 100 and the additional layer 230. The additional layer 230 is disposed between the interface layer 210 and the electrical insulator 220 The bulk layer 220 is disposed between the additional layer 230 and the gate electrode 21. The interface layer 210 is in direct contact with the silicon carbide body 100. The thickness t of the interface layer 210 is less or equal to 15 nm and in particular less or equal than 10 nm or 5 nm. In other examples, the interface layer 210 can have a thickness of less or equal to 4 nm, 3 nm or 2 nm or may be a monolayer (i.e., a layer which consists only of one layer of atoms or molecules). The interface layer 210 and the electrical insulator 220 in the context of FIG. 3 can consists of the same material as discussed above with regard to FIG. 2. The additional layer 230 may consist of a material that is different from the material of the interface layer 210 and from the material of the electrical insulator 220. The additional layer 230 may consist of a material selected from the group of consisting of silicon, aluminum nitride, titanium nitride, silicon nitride, aluminum oxide, silicon oxide, zirconium oxide, hafnium oxide, gadolinium oxide, lanthanum oxide, silicon oxynitride, aluminum oxynitride, zirconium silicate, zirconium aluminum oxide, and aluminosilicate.

The following will describe several stacks 2 that are contemplated by the present disclosure. However, other stacks may also be contemplated so that the discussed stacks are not understood to be limiting the general concept of the present disclosure.

In an embodiment the interface layer 210, being in direct contact with the silicon carbide body 100, consists of a material that comprises of silicon. The additional layer 230, being in direct contact with the interface layer 210, consists of a material that comprises silicon oxide, and the electrical insulator 220, being in direct contact with the additional layer 230 and with the gate electrode 21, consists of a material that comprises a high-k material or silicon oxide. In one example, the material of the interface layer 210 may be monocrystalline. In another example, the material of the interface layer 210 may be polycrystalline or amorphous.

As discussed above, the thickness t of the silicon interface layer 210 is equal to or less than 15 nm, and in particular equal to or less than 10 nm 5 nm. For example, the thickness t of the interface layer 210 may be less than or equal to 4 nm, 3 nm or 2 nm or may be a monolayer (i.e., a layer which consists only of one layer of atoms or molecules). The additional layer 230 may have a thickness of 10 nm, 20 nm, 30 nm, 40 nm, 50 nm, 60 nm, 70 nm, 80 nm, 90 nm, 100 nm or even greater.

In another embodiment the interface layer 210, being in direct contact with the silicon carbide body 100, consists of silicon. The additional layer 230, being in direct contact with the interface layer 210, consists of a material that comprises silicon nitride, and the electrical insulator 220, being in direct contact with the additional layer 230 and with the gate electrode 21, consists of a material that comprises silicon oxide or a high-k material. In one example, the material of the interface layer 210 may be monocrystalline. In another example, the material of the interface layer 210 may be polycrystalline or amorphous.

As discussed above, the thickness t of the silicon interface layer 210 is equal to or less than 15 nm, and in particular equal to or less than 10 nm or 5 nm. For example, the thickness t of the interface layer 210 may be less than or equal to 4 nm, 3 nm or 2 nm or may be a monolayer (i.e., a layer which consists only of one layer of atoms or molecules).

In yet another embodiment the interface layer 210, being in direct contact with the silicon carbide body 100, consists of a material that comprises silicon. The additional layer 230, being in direct contact with the interface layer 210, consists of a material that comprises silicon nitride, and the electrical insulator 220, being in direct contact with the additional layer 230 and with the gate electrode 21, consists of a material that comprises silicon oxide or a high-k material. In one example, the material of the interface layer 210 may be monocrystalline. In another example, the material of the interface layer 210 may be polycrystalline or amorphous.

As discussed above, the thickness t of the silicon interface layer 210 is equal to or less than 15 nm, and in particular equal to or less than 10 nm or 5 nm. For example, the thickness t of the interface layer 210 may be less than or equal to 4 nm, 3 nm or 2 nm or may be a monolayer (i.e., a layer which consists only of one layer of atoms or molecules).

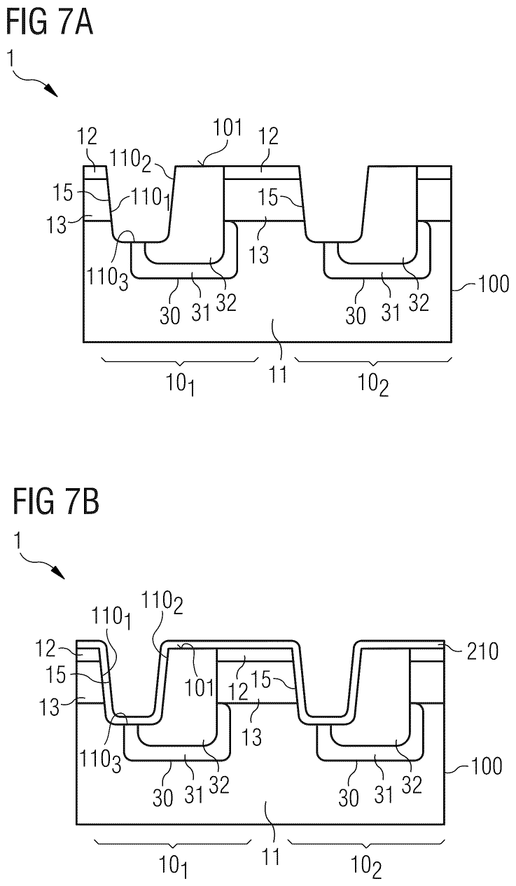

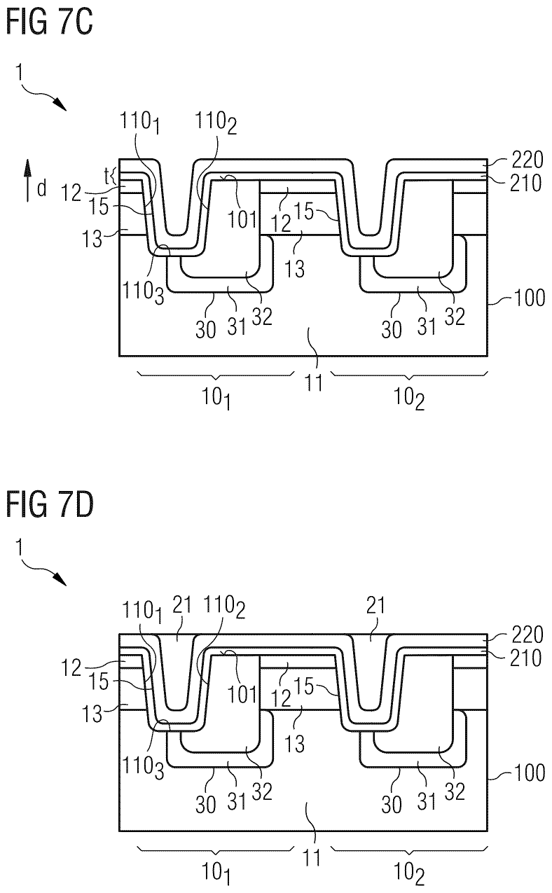

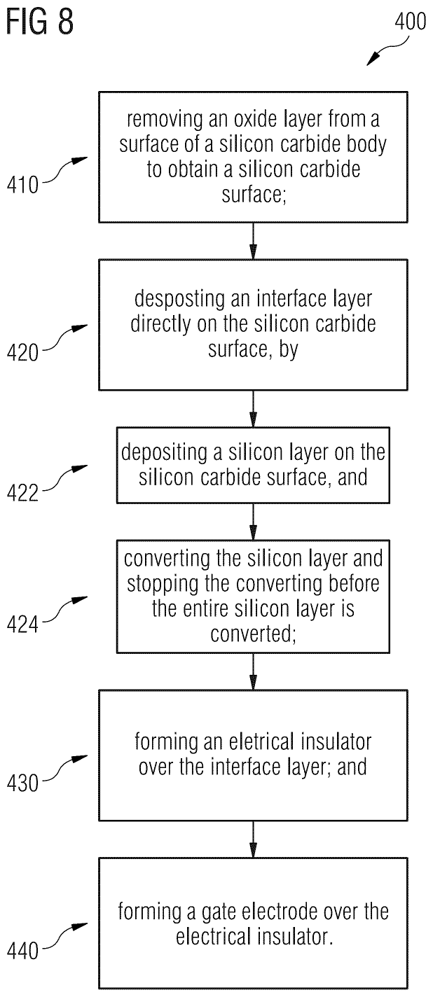

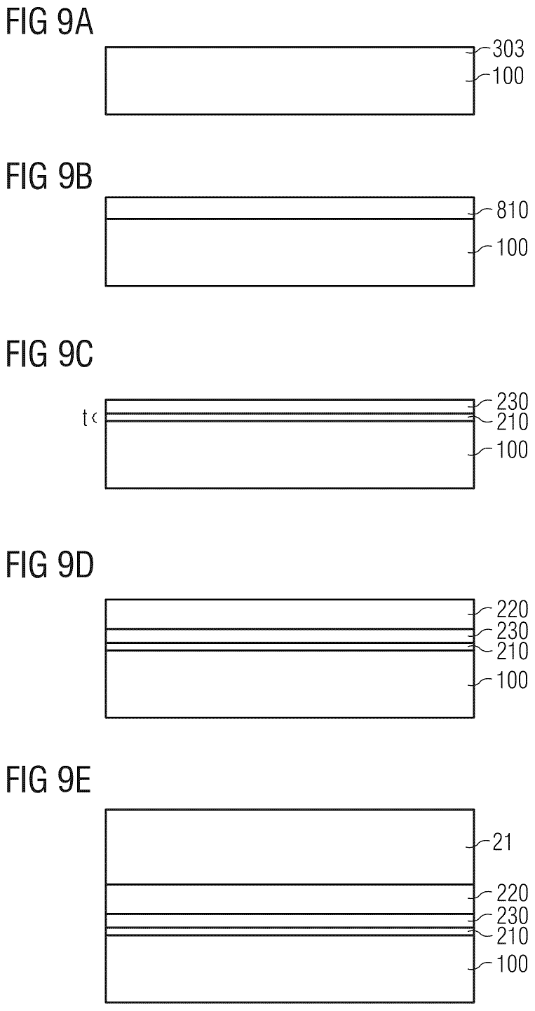

FIG. 4 illustrates a method 300 for forming an interface layer 210 on a silicon carbide body 100 of a silicon carbide device 1 in accordance with the present disclosure. The silicon carbide device may be a silicon carbide device 1 as disclosed above with regard to FIGS. 1A and 1B that includes a source region 12 of a first conductivity type and a body region 13 of a second conductivity type. In addition, the remaining components of the silicon carbide device 1 shown in FIGS. 1A and 1B may be present. The method 300 will be explained by reference to FIGS. 5A to 5D, which illustrate steps of forming the interface layer 210 for the stack 2 shown in FIG. 3, by reference to FIGS. 6A to 6D, which illustrate steps of forming the an interface layer 210 for the silicon carbide device 1 shown in FIG. 1A, and by reference to FIGS. 7A to 7D, which illustrate steps of forming an interface layer 210 for the silicon carbide device 1 shown in FIG. 1B.

The method 300 comprises removing 310 an oxide layer (such as a native oxide, a deposited oxide or a grown oxide) from a surface of a silicon carbide body 100 to obtain a silicon carbide surface 303 (e.g., a surface that substantially consists of silicon carbide, such that the surface comprises a concentration of 90% silicon carbide or more, like 95% or 99%). As shown in FIGS. 6A and 7A, this step can be performed at the first surface 101 (such as an upper surface) of the silicon carbide body 100 (e.g., in case of a lateral silicon carbide device) or in a trench (such as a gate trench) of the silicon carbide body 100 (e.g., in case of a vertical silicon carbide device), such as at one or more of the first sidewall 110₁, the second sidewall 110₂, and the bottom 110₃.

Removing 310 the oxide layer from a surface of the silicon carbide body 100 is performed to obtain a silicon carbide surface 303 that is free of oxides or substantially free of oxides (wherein substantially free of oxides may mean less than 10% of oxygen atoms on the silicon carbide surface 303) such that the silicon carbide surface 303 substantially consists of silicon carbide. An exemplary process to remove the oxide from the surface of the silicon carbide body 100 is a in situ clean process (e.g., using nitrogen trifluoride or hydrogen).

After the oxide layer is removed 310, the method 300 comprises depositing 320 an interface layer 210 on the silicon carbide surface 301.

Depositing 320 the interface layer 210 comprises depositing the interface layer 210 in direct contact with the silicon carbide surface 301 (from which the oxide was removed in step 310) that has a thickness t of less or equal to 15 nm, and in particular less or equal to 10 nm or 5 nm. In other examples, the interface layer 210 may be deposited with a thickness t of less or equal to 4 nm, 3 nm or 2 nm or may be a monolayer (i.e., a layer which consists only of one layer of atoms or molecules). The material of the interface layer 210 was explained already above with regard to FIGS. 2 and 3 and is not repeated here for brevity. As shown in FIGS. 6B and 7B, the step of depositing 320 the interface layer 210 can be performed at the first surface 101 (such as an upper surface) of the silicon carbide body 100 (e.g., in case of a lateral silicon carbide device) or in a trench (such as a gate trench) of the silicon carbide body 100 (e.g., in case of a vertical silicon carbide device), such as at one or more of the first sidewall 110₁, the second sidewall 110₂, and the bottom 110₃.

Subsequently, the method 300 comprises forming 330 an electrical insulator 220 over the interface layer 210. As discussed above with reference to FIG. 2, the electrical insulator 220 may be formed 330 in direct contact with the interface layer 210 or an additional layer 230 (or multiple additional layers) may be formed in between the interface layer 210 and the electrical insulator 220 (as discussed above with regard to FIG. 3). The electrical insulator may consist of a material that is different from the material of the interface layer 210 (and different from the material of the additional layer 230 if this is present). The bulk layer may be formed by ALD or may be deposited (e.g., via chemical vapor deposition, such as low pressure chemical vapor deposition or molecular vapor deposition). As shown in FIGS. 6C and 7C, this step can be performed at the first surface 101 (such as an upper surface) of the silicon carbide body 100 (e.g., in case of a lateral silicon carbide device) or in a trench (such as a gate trench) of the silicon carbide body 100 (e.g., in case of a vertical silicon carbide device), such as at one or more of the first sidewall 110₁, the second sidewall 110₂, and the bottom 110₃.

Optionally, before the step of forming 330 the electrical insulator 220, the method 300 may comprise forming 325 one or more additional layers 230 in direct contact with the interface layer 210. The electrical insulator 220 is then formed 330 in direct contact with one of the additional layers 230.

The steps of depositing 320 the interface layer 210, and (optionally) forming 325 the one or more additional layers 230 may be performed using atomic layer deposition (ALD). As such, the step of depositing 320 the interface layer 210 may comprise depositing a material, via ALD on the silicon carbide surface 303, wherein the deposited material forms the interface layer 210 (e.g., the interface layer 210 consists of the deposited material). The material may be homogenously deposited so that the material of the interface layer 210 is homogenous. In some embodiments, the material may comprise a first compound and a second compound. In this case, during the ALD, a ratio of the concentration of the first compound to the concentration of the second compound may vary. For example, in the beginning this ratio may be 100:0 and this ratio will be continuously altered to become 0:100 at the end of the ALD (or vice versa). This process may yield an interface layer 210 that consists of the deposited material (comprising the first and second compounds) with a concentration of the first compound of the material decreasing along a direction (d) that points from the first surface 301 of the interface layer 210 to a second surface 302 of the interface layer 210 that is opposing the first surface 301, and a concentration of the second compound of the material increasing along the direction d that points from the first surface 301 to the second surface 302 (or vice versa). For example, the first compound may be deposited, via ALD directly on the silicon carbide surface 303 for a first period of time, and the second compound may be deposited via ALD over the silicon carbide surface 303 for a second period of time. The first compound may be selected from the group consisting of silicon, aluminum, titanium, zirconium, hafnium, gadolinium, yttrium and lanthanum, and the second compound may be selected from the group consisting of oxygen, nitrogen and oxynitride, or vice versa.

Subsequently, the method 300 comprises forming 340 a gate electrode 21 over the electrical insulator 220. For example, the gate electrode 21 may be in direct contact with the electrical insulator 220. The gate electrode 21 may be made, for example, of polycrystalline silicon, titanium or aluminum. As shown in FIGS. 6D and 7D, this step can be performed at the first surface 101 (such as an upper surface) of the silicon carbide body 100 (e.g., in case of a lateral silicon carbide device) or in a trench (such as a gate trench) of the silicon carbide body 100 (e.g., in case of a vertical silicon carbide device), such as at one or more of the first sidewall 110₁, the second sidewall 110₂, and the bottom 110₃. As can be seen in FIG. 6D, the electrode may be located adjacent to the body region 13 and between the source electrode 41 and the drain electrode 43 for a lateral silicon carbide device. Alternatively, as can be seen in FIG. 7D, the gate electrode 22 can be located in a trench. The gate electrode 22 may be formed by filing the trench with a material of the gate electrode 22.

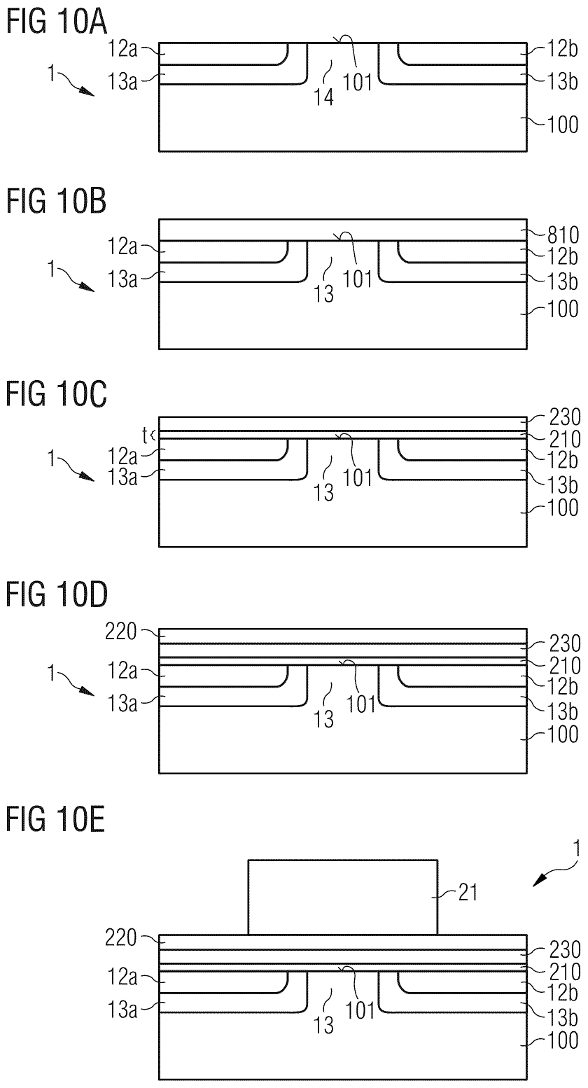

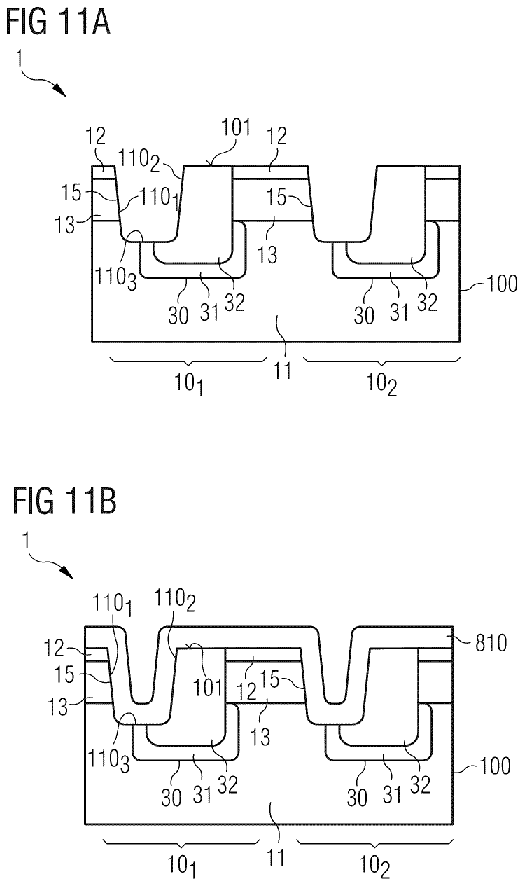

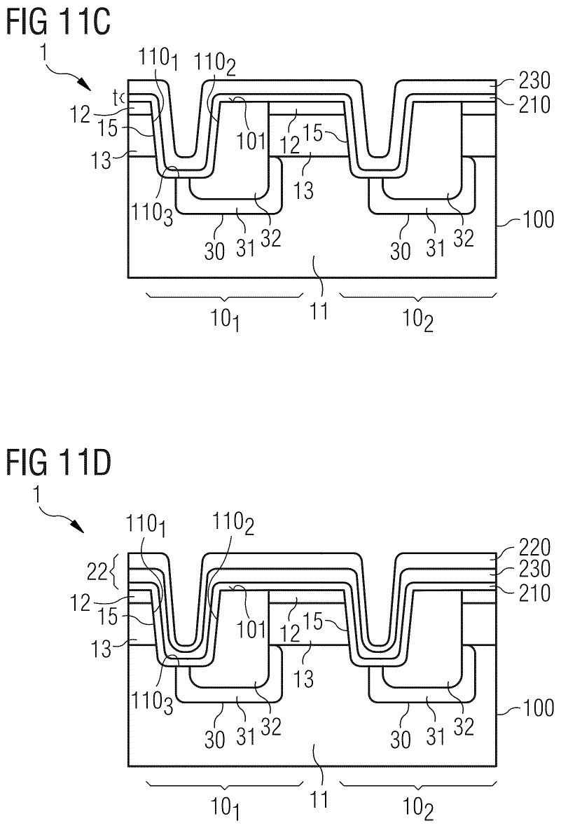

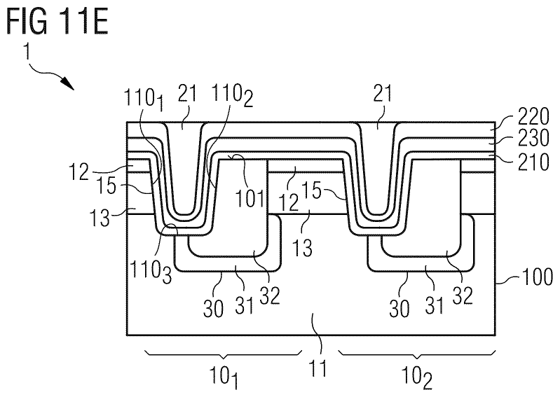

FIG. 8 illustrates a method 400 for forming an interface layer 210 on a silicon carbide body 100 of a silicon carbide device 1 in accordance with the present disclosure. The silicon carbide device may be a silicon carbide device 1 as disclosed above with regard to FIGS. 1A and 1B that includes a source region 12 of a first conductivity type and a body region 13 of a second conductivity type. In addition, the remaining components of the silicon carbide device 1 shown in FIGS. 1A and 1B may be present. The method 400 will be explained by reference to FIGS. 9A to 9E, which illustrate steps of forming the stack 2 shown in FIG. 3, by reference to FIGS. 10A to 10E, which illustrate steps of forming the silicon carbide device 1 shown in FIG. 1A, and by reference to FIGS. 11A to 11E, which illustrate steps of forming the silicon carbide device 1 shown in FIG. 1B.

Similar to method 300, method 400 comprises the steps of removing 410 an oxide layer from a surface of a silicon carbide body 100 to obtain a silicon carbide surface 303, after removing the oxide layer, depositing 420 an interface layer 210 on the silicon carbide surface 303, forming 430 an electrical insulator 220 over the interface layer 210, and forming 440 a gate electrode 21 over the electrical insulator 220. The steps of removing 410 the oxide layer and forming 440 the gate electrode 21 of method 400 may be the same as corresponding steps 310 and 340 of method 300 as discussed above.

Just as discussed above with regard to method 300, the step of depositing 420 the interface layer 210 on the silicon carbide surface 303 in accordance with method 400, comprises depositing the interface layer 210 in direct contact with the silicon carbide surface 303. According to method 400, the step of depositing 420 the interface layer 210 corresponds to depositing a silicon layer 810 on the silicon carbide surface 303. In some embodiments, the silicon layer 810 has a thickness of less or equal to 15 nm or 10 nm. In other embodiments, the silicon layer 810 may also be thicker, depending on circumstances. For example, in case the silicon layer 810 is converted (such as oxidized) into the additional layer 230 or into the electrical insulator 210 (as further discussed below), the thickness of the silicon layer may define the sum of the thickness of the interface layer 210 and the additional layer 230 (or the electrical insulator 210). In such a case the thickness of the silicon layer 810 may be 100 nm or greater.

Further, he step of forming 325 the additional layer 230 or the step of forming 330 the electrical insulator 220 corresponds to converting 425 the silicon layer 810 and stopping the converting 424 before the entire silicon layer 810 is converted to obtain a converted layer (which is the additional layer 230 or the electrical insulator 220, depending on application) formed by the converted silicon layer and a remaining silicon layer (which is the interface layer 210) of the silicon layer 810. In case the converted layer is used as the additional layer 230, a further step of forming the electrical insulator 220 may be present (e.g., to obtain a stack where the interface layer 210 is made of silicon, the additional layer 230 is made of silicon oxide, and the electrical insulator is made of a high-k material).

Depositing 420 the silicon layer 810 may comprise depositing the silicon layer with a thickness of less or equal to 5 nm or 4 nm or 3 nm or 2 nm. In particular, depositing a very thin silicon layer 810 (such as about 3 nm or thinner) may cause the silicon layer 810 to be formed in a monocrystalline structure. In this case, the silicon layer 810 may be strained and no relaxation may take place. Alternatively, the silicon layer 810 may also be formed in a polycrystalline or in an amorphous structure.

The step of converting 425 the silicon layer 810 may comprise oxidizing and/or nitriding a part of the silicon layer 810. The oxidizing and/or nitriding is stopped before the entire silicon layer 810 is oxidized and/or nitrided. The oxidized and/or nitrided part of the silicon layer 810 is the additional layer 230 (or the electrical insulator 220, as discussed above) and the remaining silicon layer (which is not oxidized and/or nitride) is the interface layer 210. In other words, the silicon layer 810 may form the basis for both the interface layer 210 and the additional layer 230 (or the electrical insulator 220), and the additional layer (or the electrical insulator) is obtained by oxidizing and/or nitriding a part of the silicon layer 810. The stopping of the converting 425 of the silicon layer 810 may be performed such that the remaining silicon layer (i.e., the interface layer has a thickness of 1 nm or less (such as one to three monolayers of silicon). In other examples, the thickness of the remaining silicon layer may also be thicker than 1 nm. The stopping of the converting 425 may be achieved by low temperature oxidation which slows down after a few nm or after a few tens of nm (such as a self-limiting radox process).

Although specific examples have been illustrated and described herein, it will be appreciated by those of ordinary skill in the art that a variety of alternate and/or equivalent implementations may be substituted for the specific examples shown and described without departing from the scope of the disclosed subject matter. This application is intended to cover any adaptations or variations of the specific examples discussed herein. Therefore, it is intended that the disclosed subject matter be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the disclosed subject matter and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the disclosed subject matter, as well as specific examples thereof, are intended to encompass equivalents thereof.

1. A method for forming an interface layer on a silicon carbide body, wherein the silicon carbide body comprises a source region of a first conductivity type and a body region of a second conductivity type, the method comprising:
removing an oxide layer from a surface of a silicon carbide body to obtain a silicon carbide surface;
after removing the oxide layer, depositing an interface layer directly on the silicon carbide surface, wherein the interface layer has a thickness of less or equal to 15 nm;
forming an electrical insulator over the interface layer; and
forming a gate electrode over the electrical insulator.

2. The method of claim 1,
wherein depositing the interface layer comprises depositing a material, via atomic layer deposition (ALD) on the silicon carbide surface,
wherein the deposited material forms the interface layer.

3. The method of claim 2,
wherein the material is comprises at least one of silicon, aluminum nitride, titanium nitride, silicon nitride, aluminum oxide, silicon oxide, zirconium oxide, hafnium oxide, gadolinium oxide, lanthanum oxide, silicon oxynitride, aluminum oxynitride, zirconium silicate, zirconium aluminum oxide, yttrium oxide, or aluminosilicate.

4. The method of claim 2,
wherein depositing the material via ALD comprises:
depositing a first compound via ALD directly on the silicon carbide surface for a first period of time; and
depositing a second compound via ALD over the silicon carbide surface for a second period of time,
wherein the first period of time initiates before the second period of time.

5. The method of claim 4,
wherein the first compound comprises at least one of silicon, aluminum, titanium, zirconium, hafnium, gadolinium, tantalum, yttrium, or lanthanum, and
wherein the second compound comprises at least one of oxide, nitride, or oxynitride.

6. The method of claim 4,
wherein the first compound comprises at least one of oxide, nitride, or oxynitride, and
wherein the second compound comprises at least one of silicon, aluminum, titanium, zirconium, hafnium, gadolinium tantalum, yttrium, or lanthanum.

7. The method of claim 1,
wherein depositing the interface layer comprises:
depositing a silicon layer on the silicon carbide surface; and
converting some but not all of the silicon layer to obtain a converted layer comprising a converted silicon layer portion and a silicon layer portion,
wherein the silicon layer portion interfaces with the silicon carbide body, and
wherein the converted layer comprises at least one of the electrical insulator or an additional layer between the interface layer and the electrical insulator.

8. The method of claim 7,
wherein the interface layer has a thickness of smaller or equal to 2 nm.

9. The method of claim 7,
wherein converting some but not all of the silicon layer comprises at least one of oxidizing at least some of the silicon layer and nitriding at least some of the silicon layer so that the converted layer comprises at least one of a silicon oxide layer, a silicon nitride layer, or a silicon oxynitride layer.

10. The method of claim 1,
wherein the electrical insulator comprises at least one of silicon oxide or of a high-k material.

11. A silicon carbide device, comprising:
a source region of a first conductivity type formed in a silicon carbide body, a body region of a second conductivity type formed in the silicon carbide body, and a drain region;
a gate electrode configured to switch a current between the source region and the drain region;
an interface layer disposed directly on the silicon carbide body and arranged between the silicon carbide body and the gate electrode,
wherein a thickness of the interface layer is less or equal to 15 nm,
wherein the interface layer comprises a first surface that is in contact with the silicon carbide body and a second surface,
wherein a concentration of carbon within the interface layer decreases along a direction that points from the first surface to the second surface from a first concentration of carbon at the first surface of the interface layer to a second concentration of carbon at a second surface of the interface layer; and
an electrical insulator disposed between the interface layer and the gate electrode and configured to electrically insulate the gate electrode from the silicon carbide body.

12. The silicon carbide device of claim 11,
wherein the concentration of carbon is less than half of the first concentration within at least 75% of the interface layer.

13. The silicon carbide device of claim 11,
wherein the interface layer comprises at least one of a material selected from the group consisting of silicon, aluminum nitride, titanium nitride, silicon nitride, aluminum oxide, silicon oxide, zirconium oxide, hafnium oxide, gadolinium oxide, lanthanum oxide, silicon oxynitride, aluminum oxynitride, zirconium silicate, zirconium aluminum oxide, tantalum oxide, yttrium oxide, or aluminosilicate.

14. The silicon carbide device of claim 11,
wherein the interface layer comprises a first compound and a second compound,
wherein the first compound comprises at least one of silicon, aluminum, titanium, zirconium, hafnium, gadolinium, tantalum, or lanthanum,
wherein the second compound comprises at least one of oxygen, nitrogen, or oxynitride,
wherein a concentration of the first compound of the material decreases along the direction that points from the first surface to the second surface, and
wherein a concentration of the second compound of the material increases along the direction that points from the first surface to the second surface.

15. The silicon carbide device of claim 11,
wherein the interface layer comprises a first compound and a second compound,
wherein the first compound comprises at least one of oxygen, nitrogen, or oxynitride,
wherein the second compound comprises at least one of silicon, aluminum, titanium, zirconium, hafnium, gadolinium, tantalum, yttrium, or lanthanum,
wherein a concentration of the first compound of the material decreases along the direction that points from the first surface to the second surface, and
wherein a concentration of the second compound of the material increases along the direction that points from the first surface to the second surface.

16. The silicon carbide device of claim 11,
wherein the interface layer comprises monocrystalline silicon.

17. The silicon carbide device of claim 11,
further comprising an additional layer that comprises at least one of silicon oxide, silicon nitride, or silicon oxynitride,
wherein the additional layer is disposed between the interface layer and the electrical insulator.

18. The silicon carbide device of claim 11,
wherein the gate electrode, the interface layer and the electrical insulator are disposed in a gate trench that extends from a first main surface into the silicon carbide body; or
wherein the gate electrode, the interface layer and the electrical insulator are disposed on a first main surface of the silicon carbide body.

19. A method for forming an interface layer on a silicon carbide body, wherein the silicon carbide body comprises a source region of a first conductivity type and a body region of a second conductivity type, the method comprising:
removing an oxide layer from a surface of a silicon carbide body to obtain a silicon carbide surface;
after removing the oxide layer, depositing an interface layer directly on the silicon carbide surface;
forming an electrical insulator over the interface layer; and
forming a gate electrode over the electrical insulator.

20. The method of claim 19,
wherein depositing the interface layer comprises depositing a material, via atomic layer deposition (ALD) on the silicon carbide surface,
wherein the deposited material forms the interface layer.
